(19) United States
(12) Patent Application Publication
(10) Pub. No.: US 2026/0044636 A1
(43) Pub. Date: Feb. 12, 2026

(54) Construction Process Support System Using Grid Labels

(71) Applicant: ACIMUS Inc., Tokyo (JP)

(72) Inventor: Koki Kikuchi, Tokyo (JP)

(73) Assignee: ACIMUS Inc., Tokyo (JP)

(21) Appl. No.: 19/294,264

(22) Filed: Aug. 7, 2025

(30) Foreign Application Priority Data
Aug. 8, 2024 (JP) 2024-133695

(51) Int. Cl. G06F 30/12; G06N 3/042

(52) U.S. Cl. CPC G06F 30/12; G06N 3/042

(57) ABSTRACT

A construction process support system that enables diverse users to quickly and intuitively create construction model data according to their intentions using natural language input and grid-based positioning. The system comprises hardware processors, software modules, and databases configured to display user interface pages to terminals and control natural language input messages. When input messages contain grid labels that specify coordinates on pages with character codes regarding construction structures, the system requests a Large Language Model (LLM) to generate instruction codes describing construction model data including the grid labels as position information. The LLM generates the requested instruction codes. The system stores the construction model data as searchable data in the database, forwards input messages to chat areas, and renders each structure as three-dimensional data at grid label positions on page canvases.

### CROSS-REFERENCE TO RELATED APPLICATIONS

This application is based upon and claims the benefit of priority from the prior Japanese Patent Application No. 2024-133695, filed on Aug. 8, 2024; the entire contents of which are incorporated herein by reference.

### BACKGROUND OF THE INVENTION

### Technical Field

The present invention relates to a construction process support system, method, and program that improve construction processes by enabling the use of natural language messages.

### Background Art

Conventionally, systems that support designers and people involved in construction processes, as well as construction models such as BIM (Building Information Modeling), have been proposed to advance architectural design from hand-drawn drawings to CAD and further to construction models with higher availability.

For example, JP H08-6989 A (Patent Document 1) discloses a method for specifying floor plans by designating grid-like cells (FIG. 11, paragraphs 0039 and 0045).

JP H08-293036 A (Patent Document 2) discloses a method for generating design drawings using fuzzy inference in response to abstract language input (FIG. 2(a), paragraph 0026).

JP 2019-200721 A (Patent Document 3) discloses a method that combines machine learning and BIM to generate multiple BIMs in response to image or text input instructing exterior or interior design (paragraph 0058). The method evaluates whether each BIM model matches the content of the images or text (paragraph 0060), and selects the BIM model with high evaluation (paragraph 0061) to design exteriors or interiors that match individual sensations of images or text impressions (paragraph 0020).

JP 2020-514905 A (Patent Document 4) discloses a method for positioning floor plans on geometric grids by placing design elements on grids (FIGS. 1 and 4, paragraph 0011) (paragraph 0016).

JP 7440053 B2 (Patent Document 5) discloses a method that uses a learning model to engage in dialogue with users about the content of design drawings after their registration, concerning dimensional modifications and the transportation of large musical instruments.

Additionally, the concept of BIM and case studies in Japan are reported in non-patent literature.

BALDWIN (Non-Patent Document 1) discloses methodologies and case studies of project management using BIM.

For example, while BIM models at 1:1 scale without reduction, development levels (LoD) are defined as adopted by the American Institute of Architects specifications. Scales suitable for each of the five stages are proposed: conceptual design, design development, construction documents, shop drawings, construction completion, and operation (p. 31).

When construction model data such as BIM can be utilized, not only is the administrative burden of reporting reduced, but cost-effective design is also refined, enabling design changes at optimal costs according to project progress at any time. This is explained as data utilization in 3D for three-dimensional data, 4D with the addition of time axis, and 5D with the addition of cost axis (pp. 36-40).

This BALDWIN also discloses IFC schemas for information exchange using IFC (Industry Foundation Class) models based on openBIM standard specifications as BIM documentation (pp. 74-87).

Regarding terminology, there is the buildingSMART Data Dictionary (bSDD), a buildingSMART service, where translations in English, German, French, Japanese, and other languages are provided for the following terms (p. 89):
Objects (walls, doors, floors)
Properties (fire compartment, cost)
Actors (designers, plumbing engineers, BIM managers)
Phases (design development, bidding, construction)
BIM relations (clash detection, cost estimation)
Classification systems (Omniclass, Uniclass, eBKP)

Regarding such BIM implementation, BALDWIN reports that according to informal survey results in the United States, there was an average productivity decline of 25% to 50% when introducing new BIM tools. It takes an average of 3-4 months to return to previous productivity levels (pp. 102-103).

Operational level activities are broad and diverse, including all activities from model creation, design analysis, schedule creation (for example, quantity takeoff), progress report creation, to tracking changes and defects on site.

JFMA (Non-Patent Document 2) discloses BIM utilization case studies from the perspective of facility management.

For example, in the verification of model development cases aimed at data-driven building operation, it is disclosed that operational BIM implemented selection and rejection of information unnecessary for operation from information created during design and construction (pp. 16-17).

Additionally, as BIM utilization examples, quantity estimation for large-scale condominium renovation work, construction history management, and use of elevation drawings that pick up only piping for emergency response are disclosed (pp. 20-23).

Also, though not limited to the construction field, applications of large language models and explanations of mathematical understanding are known.

For example, YAMADA et al. (Non-Patent Document 3) discloses methods for named entity recognition, summary generation, sentence embedding, and question answering as utilization examples of large language models.

In the question answering example, a program code example is disclosed that sends query messages such as “What is the highest mountain in Japan?” to OpenAl's ChatGPT as API requests and displays responses on terminals (p. 261). Additionally, a method is disclosed that defines character strings as prompts for how to respond prior to answering quizzes, such as “You will now answer quizzes” and “Problems will be given, so please output only the answers concisely,” and calls APIs with query messages as arguments (pp. 266-267).

IMAIZUMI (Non-Patent Document 4) discloses research examples of mathematical analysis of large language models.

For example, on p. 37, arbitrary function approximation using trigonometric functions in Fourier transform is exemplified as a conventional machine learning method. In this case, neural networks need only two layers and do not require multiple layers.

However, large language models are multi-layered, and it is analyzed that multi-layer neural networks succeeded because they can express functions with non-smooth jump structures (p. 39). It is said that multi-layer neural networks have smaller approximation errors even for functions where smoothness and periodicity change discontinuously.

Multi-layer neural networks in large language models can approximate the complexity of natural language that cannot be approximated by ordinary trigonometric functions, and can store it as parameter groups in vector space. While it is difficult to completely control the information processing that determines the parameters of multi-layer neural networks, it is known that when correct answers are given and processing is performed to reduce errors in the reverse direction (backpropagation method), the values of multi-layer and large-scale parameter groups become values that well approximate the training data.

Large language models can convert natural sentences used by humans into other languages or code, and generate plausible sentences with high probability that follow questions, by probabilistically predicting words (tokens) that appear in sentence continuations. Currently, dialogue with large language models has evolved to a level where it is not easy to determine whether the counterpart is a real human. On the other hand, for questions about content that has not been learned, they generate sentences with completely different content in formally plausible writing styles, or answers that do not exist in reality (hallucination).

The least squares method is also a technique for approximating functions by minimizing errors with data, but it is known that the resulting equations cannot predict when applied to phenomena outside the range of sample data. Even with the backpropagation method that reduces errors, hallucination for areas outside the training data can be technically anticipated as unavoidable.

YAMADA et al. state regarding hallucination: “Even when the (large language) model does not possess the knowledge necessary for answering, it generates tokens [ . . . ] and is considered to have exhibited behavior of outputting plausible restaurant names that exist in the training corpus (as hallucination)” (p. 76).

At the time of filing, no method has been proposed to fundamentally eliminate hallucination in large language models, and attempts are being made to suppress the occurrence of hallucination by providing some guidance in individual applications while operating within the range of training data.

Large language models may generate numbers with similar meaning or format as part of text (tokens) without performing actual calculations, and it can be difficult even to calculate the sum of numbers that appear in the chronological sequence of chat.

Regarding architectural design and the overall construction process, if construction model data such as BIM could be utilized, costs would be reduced and reporting would be automated, allowing people working in the construction industry to focus on what they should originally be doing, which would also reduce stress. However, the introduction of BIM and similar systems presents high barriers not only in terms of cost but also in human resources.

As shown in each of the above patent documents, there are proposals to utilize language input, grids, BIM, machine learning, and other technologies in architectural design. However, construction model data has not penetrated construction sites and construction processes, and not only has productivity not improved, but labor shortages have occurred due to stress from excessive unnecessary work.

Even though it is understood that utilizing construction model data throughout the entire architectural value chain and even for post-construction operation would be efficient, the barrier to entry for inputting construction model data and digitizing it for practical use is extremely high, and it has not penetrated the industry.

Additionally, methods for supporting the creation and design of construction model data that can be converted to BIM covering not only exteriors and interiors by applying large language models are not known. Using large language models alone results in unstable handling of numerical values such as dimensions, making it difficult to stably generate consistent construction model data. The possibility of generating extremely unnatural data as hallucination for construction models cannot be controlled, which would instead require time for verification.

### PRIOR ART DOCUMENTS

### Patent Documents

[Patent Document 1] JP H08-006989 A1
[Patent Document 2] JP H08-293036 A1
[Patent Document 3] JP 2019-200721 A1
[Patent Document 4] JP 2020-514905 A1
[Patent Document 5] JP 7440053 B2

### Non-Patent Documents

[Non-Patent Document 1] BALDWIN [2022]
[Non-Patent Document 2] JFMA [2022]
[Non-Patent Document 3] YAMADA et al. [2023]
[Non-Patent Document 4] IMAIZUMI [2021]

### SUMMARY OF THE INVENTION

### Problem to be Solved by the Invention

Technical Challenges: The above conventional examples and their combinations have the inconvenience that it is difficult to widely disseminate the input of construction model data. Furthermore, the above conventional examples have the inconvenience that it is not possible to create (design) construction model data that is consistent as a construction model while using large language models.

For example, even when attempting to apply large language models to architectural design, the handling of coordinate values and units tends to be inconsistent, making practical application difficult.

Object of the Invention: The object of the present invention is to provide a construction process support system, method, and program that can improve the entire construction process by enabling diverse personnel to quickly create construction model data as desired, thereby flexibly responding to client needs.

### Technical Solution

Focus Point: The inventor of the present invention conducted various thinking, research, and experiments, gained insight into the challenges of the construction industry, and found the relationship that in order to eliminate inefficiencies associated with construction and allow people to focus on traditional, essential, and creative work, it would be good to first enable the creation of construction model data that is consistent as a construction model simply by giving natural instructions.

Therefore, the inventor arrived at the idea that in order to utilize the original functions of large language models to enable design in natural language while accumulating consistent construction model data, it is first necessary to devise the handling of coordinate values of structures.

Solution 1: Therefore, the first group of the present invention corresponding to Embodiment 1 comprises a rendering unit (10) that controls display of pages (06) serving as user interfaces connected to user terminals (02), a controller (20) that controls input messages (11) inputted as natural language data from the terminals (02) to the rendering unit (10), an LLM unit (30) that generates instruction codes (31) describing construction model data (41) by referring to the input messages (11), and a construction model database (40) that stores the construction model data (41) corresponding to the instruction codes (31) in a searchable manner.

The controller (20) includes position information process (22) that causes the LLM unit (30) to generate the instruction codes (31) using grid labels (21) that specify coordinates on the pages (06) with character codes as position information of the structures when the grid labels (21) are included in the input messages (11) of construction structures.

Furthermore, the rendering unit (10) includes chat process (14) that controls display of the input messages (11) in chat areas (07) of the pages (06), and three-dimensional rendering process (15) that controls display of three-dimensional data (13) of each structure of the construction model data (41) read from the construction model database (40) at positions specified by the grid labels (21) of each structure in canvases (08) within the pages (06).

This solves the technical problem of creating consistent construction model data with only natural instructions.

Solution 2: The second group of the present invention corresponding to Embodiment 2 includes completion process (23) in which the controller (20) causes the LLM unit (30) to refer to predetermined construction standard data (51) and complement the construction model data (41) that is insufficient in the input messages (11) regarding the structures in the context corresponding to conversations with the user through the natural language data.

The rendering unit (10) includes surface process (16) that processes surfaces of the three-dimensional data (13) according to materials of the structures specified by the user or complemented.

This solves the above technical problem of enabling creation of construction model data without excess or deficiency.

Solution 3: The third group of the present invention corresponding to Embodiment 3 includes input promotion processing (28) in which the controller (20) causes the LLM unit (30) to refer to design process data (54) predetermined as standard design processes and generate reply messages (12) that prompt input of content to be designed following the state of the construction model data (41).

This solves the technical problem of enabling diverse people to execute natural and high-quality design in standard processes without stress.

### Technological Advancement

The present invention, when interpreting the meaning of terms described in each claim in consideration of the description and drawings of this specification and recognizing the invention according to each claim, operates as described below and produces the following advantageous effects in relation to the above background art and the like.

Technical improvement 1: In the construction process support system of Problem Solving Means 1, the position information process (22) of the controller (20) causes the LLM unit (30) to generate instruction codes (31) that use grid labels (21) as position information of the structures when grid labels (21) are included in the input messages (11). The LLM unit (30), under control by the controller (20), refers to the input messages (11) and generates instruction codes (31) that describe construction model data (41) using grid labels (21).

The rendering unit (10), through its three-dimensional rendering process (15), converts each structure of the construction model data (41) read from the construction model database (40) into three-dimensional data (13) at positions specified by the grid labels (21) of each structure in the canvas (08) within the page (06) and controls their display.

Therefore, position information can be handled not as numerical values themselves but as character codes called grid labels among input messages (11) in natural language, instruction codes (31) that operate the construction model database (40), construction model data (41), and three-dimensional data (13). Position information that maintains identity without change through natural language processing from input messages (11) to three-dimensional data (13) can be handled.

Consequently, while accepting creation of construction model data through input messages (11) in natural language by the LLM unit (30), coordinate values can be handled strictly, and as a result, construction model data consistent as construction models can be designed and accumulated.

The present invention can thus accumulate consistent construction model data while using the LLM unit (30) as a component, making it easier to conduct trial-and-error design according to client needs and requirements, allowing humans to concentrate on tasks they should originally perform, and accumulating construction model data (41) that enhances the satisfaction of clients and other orderers.

Technical improvement 2: In the construction process support system of Problem Solving Means 2, since the completion process (23) causes the LLM unit (30) to refer to standard data (51) and complement construction model data (41) that is insufficient in the input messages (11) regarding structures, users do not need to input even routine details about structure attributes, and can create construction model data through input messages (11) in natural language with only the minimum essential content.

The three-dimensional rendering process (15) generates sets of structures as three-dimensional data (13) using coordinate values of grid labels (21). At this time, since the surface process (16) processes the surfaces of structures according to materials of the structures specified by the user or complemented, the surfaces of three-dimensional data (13) are processed with materials for each structure regarding the latest information of construction model data (41). Therefore, construction models can be visually confirmed with three-dimensional data (13) having textured surfaces where it is visually recognizable that concrete, wood, or other materials have been specified.

Thus, since the completion process (23) complements from standard data (51), users can register consistent construction model data without excess or deficiency with minimal instructions.

This enables accumulation of construction model data (41) that has sufficient quality as architectural design while creating construction model data (41) in natural language, can be utilized throughout the entire value chain of construction processes, and can be usefully employed in post-completion operations.

Technical improvement 3: In the construction process support system of Problem Solving Means 3, since the input promotion processing (28) causes the LLM unit (30) to refer to design process data (54) and generate reply messages (12) that prompt input of content to be designed following the state of construction model data (41), input in a standard and desirable order as a design process can be encouraged, and users can be asked to make decisions so that no items are missing from the construction model data (41).

Users can naturally learn through message-based dialogue what content should be input following the state of the latest construction model data (41) according to previous inputs, and can examine essentially required matters in a desirable order without stress in the standard order of design.

This suppresses wasteful work in design phases, enables diverse people to execute natural and high-quality design in standard processes without stress, and can provide users with productive and fulfilling work experiences.

Since consistent construction model data (41) without excess or deficiency can be created by answering questions in natural language in an orderly manner without advanced learning of IT or CAD, diverse personnel can quickly create construction model data as desired, and as a result, utilization of construction model data (41) can be broadly delivered to the construction industry.

### BRIEF DESCRIPTION OF DRAWINGS

FIG. 1 shows a block diagram of a configuration example of a construction process support system that controls grid labels. (Embodiment 1)

FIG. 2 shows an explanatory diagram of an example of a page. (Embodiment 1) FIG. 3 shows an explanatory diagram of an example of construction model data. (Embodiment 1)

FIG. 4 shows a flowchart of a construction model data creation process using natural language and grid labels. (Embodiment 1)

FIG. 5 shows a block diagram of a configuration example of a construction process support system that refers to design standard data. (Embodiment 2)

FIG. 6 shows an explanatory diagram of an example of design standard data. (Embodiment 2)

FIG. 7 shows a sequence diagram of a construction model data creation process using completion process that refers to design standard data. (Embodiment 2)

FIG. 8 shows an explanatory diagram of an example of error messages. (Embodiment 2) FIG. 9 shows a flowchart of a processing example using error messages. (Embodiment 2) FIG. 10 shows a block diagram of a configuration example of a construction process support system that refers to design process data. (Embodiment 3)

FIG. 11 shows an explanatory diagram of an example of a page before placing a living room on the canvas. (Embodiment 3)

FIG. 12 shows an explanatory diagram of an example of a page with a living room placed on the canvas. (Embodiment 3)

FIG. 13 shows an explanatory diagram of an example of a page with the living room position changed. (Embodiment 3)

FIG. 14 shows an explanatory diagram of an example of a page with columns placed at the corners of the living room. (Embodiment 3)

FIG. 15 shows an explanatory diagram of an example of a page with a reply about the state of the living room columns in the chat area. (Embodiment 3)

FIG. 16 shows an explanatory diagram of an example of a page with one of the columns deleted. (Embodiment 3)

FIG. 17 shows a business design sheet explaining the industrial applicability of this embodiment. (Embodiments 1, 2, 3, and 4)

### DETAILED DESCRIPTION

Four embodiments are disclosed as forms for carrying out the invention. Embodiment 1 is a construction process support system, method, and program that uses grid labels 21.

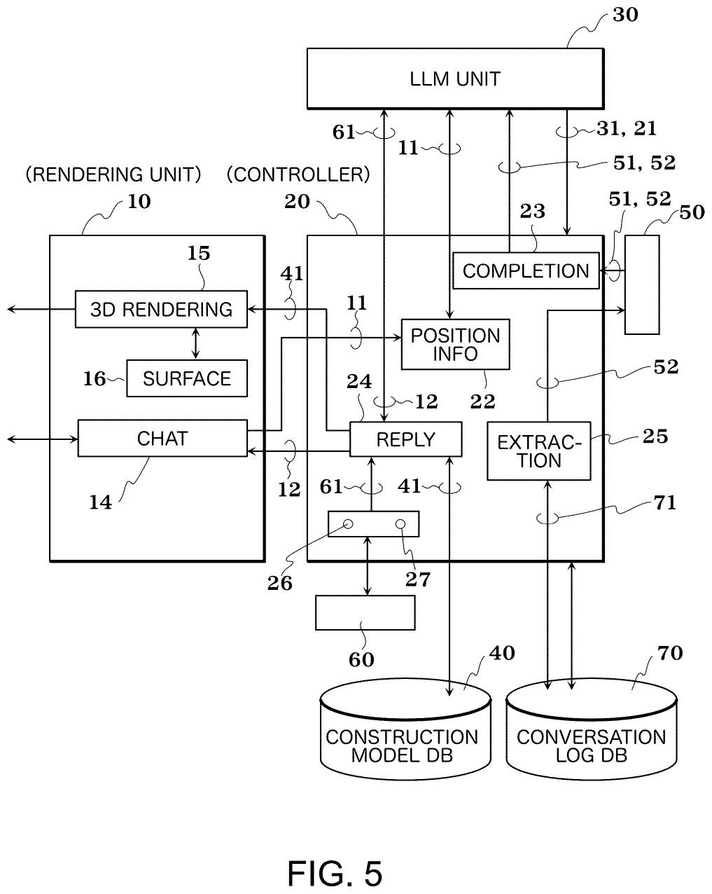

Embodiment 2 is a construction process support system, method, and program that performs completion process 23 by referring to standard data 51 shown in FIG. 5 and other figures. Usage examples of conversation logs 71 and error messages 61 are also disclosed as Embodiment 2.

Embodiment 3 is a construction process support system, method, and program that promotes user input by referring to design process data 54 shown in FIG. 10 and other figures.

Embodiment 4 is a case that has the functions of Embodiments 1 to 3 and adds further practical functions.

Embodiments 1 to 4 are collectively referred to as embodiments.

The system, method, and program inventions according to this embodiment are software-related inventions and require hardware resources for their implementation.

Each component and each process of the embodiment is a group of programs executable by processors of one or more computers. A computer has a processor (arithmetic apparatus), memory (main storage device and auxiliary storage device), bus, input/output devices, network control, and the like.

Programs may directly execute processor instructions, but can be written in programming languages that assume operating systems, browsers, or various APIs, and can be executed as-is or compiled to create executable code.

The system and method according to this embodiment may be executed on a single computer or on multiple computers connected by network 4.

For example, the controller 20 can be implemented on an operating system of a computer connected to the display of a terminal. Display control of three-dimensional data 13 by the rendering unit 10 can be implemented with script language APIs that operate in the browser of terminal 2. The LLM unit 30 can implement basic functions by accessing servers that provide large language model services via APIs.

The construction model database 40 may also be installed on a computer connected to terminal 2, or cloud services may be utilized via network 4.

The controller 20, rendering unit 10, LLM unit 30, and each processing 14, 15, 22, etc., each perform information processing using computer processors and the like. In other words, each unit and each process uses hardware resources such as processors and memory to temporarily store input data, perform calculations, and output results. Those skilled in the art can create and use programs that reproduce the embodiments of the invention by referring to the disclosure of this embodiment while using the original functions of computers, operating systems, browsers, APIs, and hardware resources.

For example, in the embodiment, the LLM unit 30 uses limited functions that can be easily used by those skilled in the art at the time of filing. Therefore, the LLM unit 30 can be realized by accessing general chat services of large language models via APIs and adding the configuration of the embodiment.

Since all elements of the embodiment use hardware resources, where there is non-obviousness (inventive step), there is utilization of hardware resources.

The controller 20, each unit, and each process of the embodiment and each example solve the above problems respectively by organically cooperating while utilizing hardware resources, beyond the original functions that operating systems, browsers, databases, APIs, large language models, etc. normally possess at the time of filing.

For example, the ability of large language models to dialogue with users in natural language and to generate machine-readable code such as programs and queries in an executable manner is an original function of large language models at the time of filing.

In contrast to this original function, the embodiment combines reproducible elemental technologies disclosed in this specification, such as grid labels 21, instruction codes 31, construction standard data 51, and error messages 61 of each example, without special large language models, special pre-training (fine-tuning), or artisan-like prompts (input messages 11), resulting in a useful and novel configuration. This new system configuration solves each of the above problems respectively.

Hereinafter, these technologies are disclosed in detail as four embodiments. Database is abbreviated as DB.

### Embodiment 1

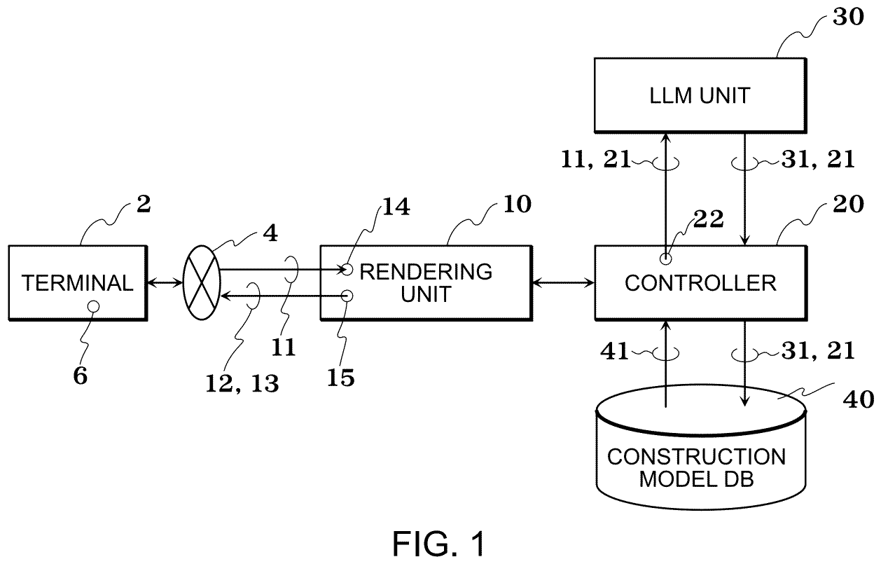

Referring to FIG. 1, the construction process support system of Embodiment 1 comprises a rendering unit 10, a controller 20, an LLM unit (natural language processing unit) 30, and a construction model database 40.

The rendering unit 10 controls display of pages 6 that serve as user interfaces connected to user terminals 2 via network 4.

The controller 20 controls input messages 11 inputted as natural language data from terminals 2 to the rendering unit 10. In this embodiment, natural language data is inputted, for example, by text input or voice input. Text input or voice input may be performed by human users, or a system that reads existing design drawings and expresses them in natural language may serve as a virtual user to perform text input or voice input. Input of input messages 11 may use data or signals that can input natural language, such as eye gaze, electromyography, or brain waves.

As control of input messages 11, the controller 20, for example, receives the input messages 11 via network 4 and analyzes their content.

The LLM unit 30 generates instruction codes 31 that describe construction model data 41 by referring to input messages 11.

The construction model database 40 stores construction model data 41 corresponding to instruction codes 31 in a searchable manner. Instruction codes 31 are queries that operate the construction model DB 40, and these queries update construction model data 41 with a certain structure as shown in FIG. 3. Therefore, instruction codes 31 can be said to be codes in markup language that describe construction model data 41 in machine-readable form.

In this Embodiment 1, the controller 20 includes position information process 22 that handles grid labels 21.

Grid labels 21 are labels that specify coordinates on page 6 with character codes, and are labels using character codes that specify coordinate values of dividing lines that divide x-coordinates and y-coordinates at equal intervals. It is preferable to combine alphabets A, B, C with numbers 1, 2, 3 to specify coordinate values with labels such as B2. It would be smooth to handle specific sequences of character code strings that can be handled with regular expressions, such as B2 and A3, as grid labels 21. Alternatively, it may be learned that characters at positions referring to position information in the context of input messages 11 are grid labels 21.

The position information process 22 causes the LLM unit 30 to generate instruction codes 31 that use grid labels 21 as position information of the structures when grid labels 21 are included in input messages 11 of construction structures (objects).

The “generation” control by position information process 22 may be achieved by having the LLM unit 30 learn grid labels 21 and their processing at startup. Alternatively, it may cause the LLM unit 30 to generate by determining whether grid labels 21 are included in input messages 11, and if included, adding to the input messages 11 that grid labels 21 are position information.

In instruction codes 31, character codes used by users such as B2 and A3 may be described as position information as-is, or may be converted to other expressions. When fixing the absolute values of grid labels 21, the description of grid labels 21 common to input messages 11, reply messages 12, instruction codes 31, and construction model data 41 can be used as position information as-is.

When the position of a structure deviates from grid labels 21, it is preferable to handle the offset amount from grid labels 21 numerically or as a ratio. In ratio handling, grid labels 21 may be hierarchized, such as “Ab3” where “b” represents a position among multiple divisions between A and B.

In the example shown in FIG. 3, columns are at the positions of grid labels 21, and the offset amount is 0 [mm]. When specifying positions with multiple grid labels 21 such as for living rooms, the position may be specified with one offset amount for the entire area, or offset amounts from each grid label 21 position may be handled.

Input messages 11 are composed in natural language, and no specific format is required except for grid labels 21. Natural language refers to languages used by humans in daily life, including written and spoken language. The LLM unit 30 (large-scale natural language model) converts these natural languages into forms that computers can interpret. Specifically, it analyzes text or voice input by users and generates replies (responses) or actions according to their content. This enables users to interact with the construction process support system through intuitive communication.

However, since large language models are unstable in handling defined data items and managing physical numerical values such as lengths, the original functions of large-scale natural language models cannot stably generate construction model data 41. Therefore, in Embodiment 1, the creation and design of construction model data 41 is stably supported through cooperation between various functions of the rendering unit 10 and controller 20 with the LLM unit 30 (large language model).

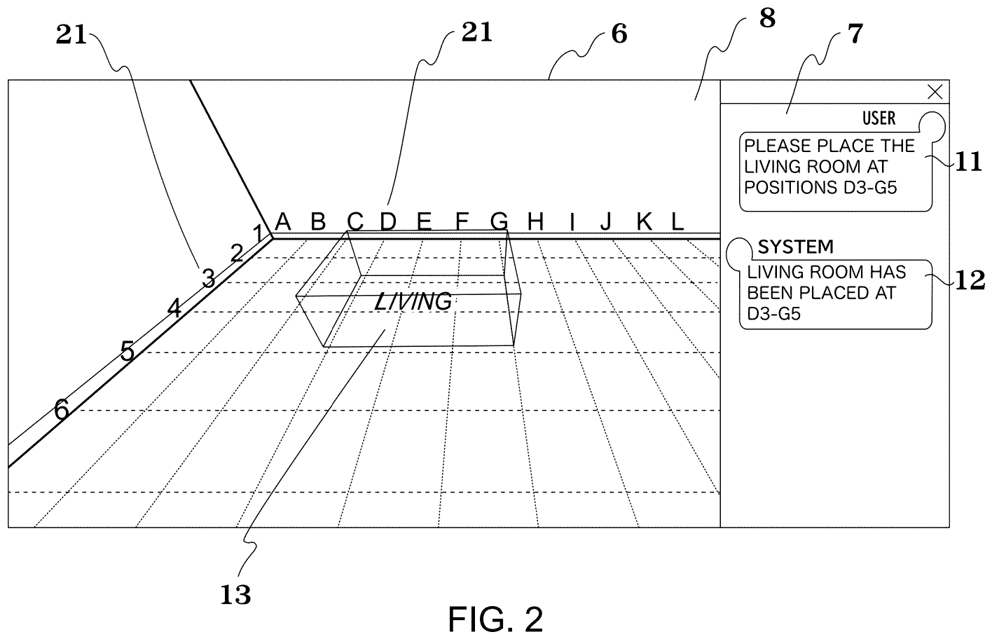

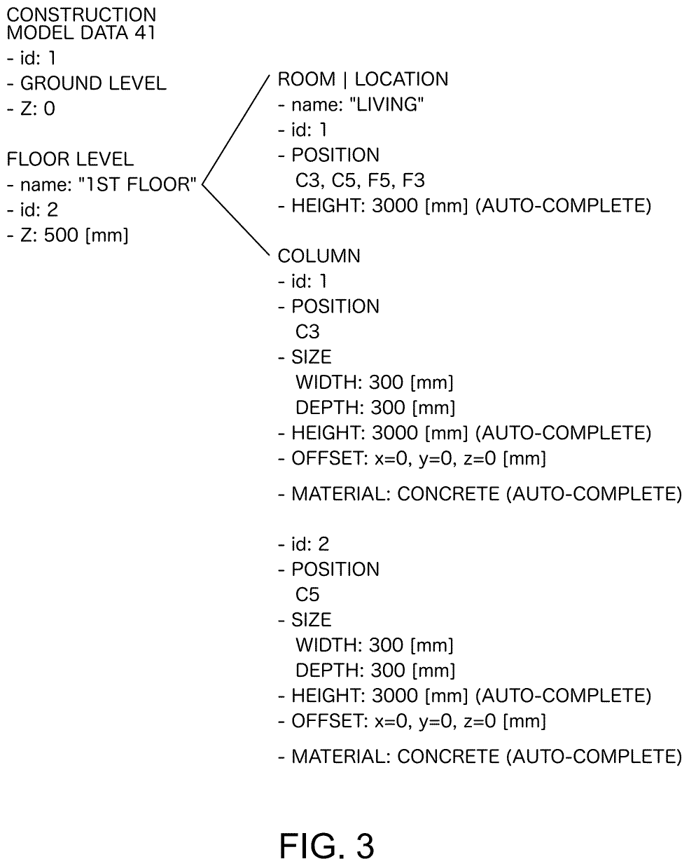

Referring to FIG. 2, page 6 is an area displayed on the display of terminal 2, and includes a chat area 7 that displays input messages 11 and the like, and a canvas 8 that visually displays coordinates (position information) to users in an easily understandable manner using grid labels 21.

In the example shown in FIG. 2, grid labels 21 specify coordinates in alphabetical order A, B, C in the horizontal direction (x-direction) in the figure, and in numerical order 1, 2, 3 in the vertical direction (y-direction) in the figure. For example, one point of xy coordinates can be specified by “D3” which combines x and y labels. For example, coordinate values of a living room on a plane are specified by an instruction (input message 11) such as “place a living room at the position from D3 to G5.” The living room is an example of three-dimensional data 13 (construction structure object).

The rendering unit 10 shown in FIG. 1 includes chat process 14 and three-dimensional rendering process 15.

Chat process 14 controls display of input messages 11 in chat area 7 of page 6. This chat process 14 can display dialogue with the construction process support system by alternately displaying input messages 11 and reply messages 12 (system responses) in chat area 7.

Three-dimensional rendering process 15 controls display of three-dimensional data 13 of each structure of construction model data 41 read from construction model DB 40 at positions specified by grid labels 21 of each structure in canvas 8 within page 6. In FIG. 2, a living room is displayed in three-dimensional form.

When displaying page 6 in a browser of terminal 2, the rendering unit 10 can be realized by executing programs that utilize APIs capable of rendering interactive two-dimensional and three-dimensional computer graphics, such as WebGL (Web Graphics Library). While the original function of programs using WebGL is to display interactive 3D object data, the rendering unit 10 of Embodiment 1 is characterized by information processing that converts construction model data 41 read from construction model DB 40 into three dimensions and controls display on canvas 8 using grid labels 21 as position information.

A database (DB) has a recording medium that electromagnetically and physically carries data representation (bits), cache, an input/output control unit that controls data input/output, and a database management system that logically manages data IDs and addresses such as records.

The construction model database 40 can utilize relational databases (RDB) that store data in data structures expressible by ER diagrams and perform registration, updating, reading, etc. with SQL statements while maintaining ACID characteristics, or NoSQL databases that handle large amounts of data flexibly and at high speed while sacrificing consistency.

In contrast to the general original functions of databases, the construction model DB 40 is characterized by storing data in the data structure of construction model data 41 specific to the embodiment as shown in FIG. 3 and responding to access requests. Therefore, even simply storing text files in XML or JSON format without using a database management system corresponds to the database of the embodiment.

Since the LLM unit 30 performs probabilistic information processing, using RDB for construction model DB 40 increases formal errors related to database operations, but allows recording with clearly keyed data structures. Recording with NoSQL databases or temporarily using JSON files or XML with tags for each item to give meaning to data while sacrificing duplication and consistency reduces errors when processing input messages 11, but makes it difficult to “always maintain formal consistency” as construction model data 41. However, if the structure shown in FIG. 3 can be secured, “consistency as a construction model” can be maintained.

As various aspects, for example, in applications where construction model data 41 is designed through trial and error, the construction model DB 40 may be configured with NoSQL or XML, and when units such as floors are completed, they may be separately stored again in RDB, ensuring formal consistency at that time.

Functions for reviewing the consistency of construction model data 41 according to design progress may be enhanced, and the construction model DB 40 may be realized with NoSQL alone. Even for large-scale buildings, the system, method, and program of Embodiment 1 can be sufficiently implemented with NoSQL.

When collaboration or synchronization with other RDBs is necessary, making the construction model database 40 an RDB will make synchronization and the like smoother. As for input-side synchronization, if existing two-dimensional design drawing data is stored in an RDB, the construction model database 40 of the embodiment may also be an RDB, and the construction model database 40 may be loaded by utilizing reading between the RDBs, and then three-dimensionalized with natural language. Of course, existing two-dimensional drawing data may be outputted in JSON or the like, and this may be read by the LLM unit 30 or the like to generate an instruction code 31 in the format shown in FIG. 3.

In any case, since three-dimensional data 13 is displayed to users for visual confirmation before updating construction model data 41, content consistency as construction model data 41 can be accumulated sequentially regardless of the database format. For issues such as the presence of interference that are cumbersome to confirm visually, depending on the embodiment, it is advisable to separately implement review processing.

Additionally, in Embodiment 1, since the construction model database 40 stores construction model data 41 corresponding to instruction codes 31 in a searchable manner, the LLM unit 30 can generate reports and two-dimensional drawings that reference construction model data 41 determined by designers using natural language processing methods that reference external information (RAG, Retrieval-Augmented Generation).

For example, when automatically generating reports such as designers' weekly reports or work reports referencing construction model data 41 for people involved in construction processes, using natural text regarding progress and content or reports with three-dimensional data 13, reliable construction model data 41 with accurate numbers can be searched, preventing hallucination and enabling generation of content with accuracy suitable for business use.

A construction model is a set of data structures that can represent buildings or structures in three-dimensional digital format on computers, and is a collection of structures that are 3D objects. 3D objects (structures) are three-dimensional object information of construction components, fixtures, equipment, piping, materials, etc. that constitute construction models. In the embodiment, meaningful spaces such as living rooms and kitchens are also treated as structures.

Referring to FIG. 3, construction model data 41 has a structure of ID, name, position, shape (height), type, material, etc. for each structure.

As a hierarchical structure, floors (floor levels) are at the top level, and structures (objects) belong to each floor. Ground level with height 0 [mm] is id1, first floor is id2, and consecutive ids are assigned for each type of structure such as “ROOM| LOCATION” belonging to the first floor.

In the example shown in FIG. 3, all structures can be uniquely identified by floor level, structure type, and id. As an alternative method, consecutive ids may be assigned to all structures, but with the configuration shown in FIG. 3, ids can be displayed when displaying structures as three-dimensional data 13, and when used for dialogue with users, these id values can be used directly as natural language dialogue such as “column No. 1” and “column No. 2” and displayed on screen.

The construction model data 41 shown in FIG. 3 records values of attributes (size, height, etc.) specified in input messages 11 or automatically assigned by completion process 23 of Embodiment 2. However, even when there are no values, items that should be specified for that structure may be stored as no value or uninputted values. With such a data structure, the LLM unit 30 can identify items currently lacking for each structure by referring to the latest construction model data 41 (can be used in input promotion process 28 of Embodiment 3).

Instruction codes 31 are operation instructions to databases generated by the LLM unit 30, and in this embodiment, are codes that operate the construction model database 40 to describe construction models (structures). These instruction codes 31 are generated in response to input messages 11 that are requests from users, and are passed to controller 20.

Controller 20 operates the construction model database 40 by executing these instruction codes 31 against the construction model database 40, performing addition, updating, deletion, etc. of construction model data 41.

Instruction codes 31 are queries to databases. When the construction model database 40 is a relational database, they are SQL statements, and for NoSQL, there are various types. Instruction codes 31 are queries to databases and simultaneously codes in languages that describe construction models. For describing construction models, there are BIM IFC (Industry Foundation Classes) files and others, but as shown in FIG. 3, a description system specific to embodiments with hierarchical structures and prepared systems of structure types can be adopted.

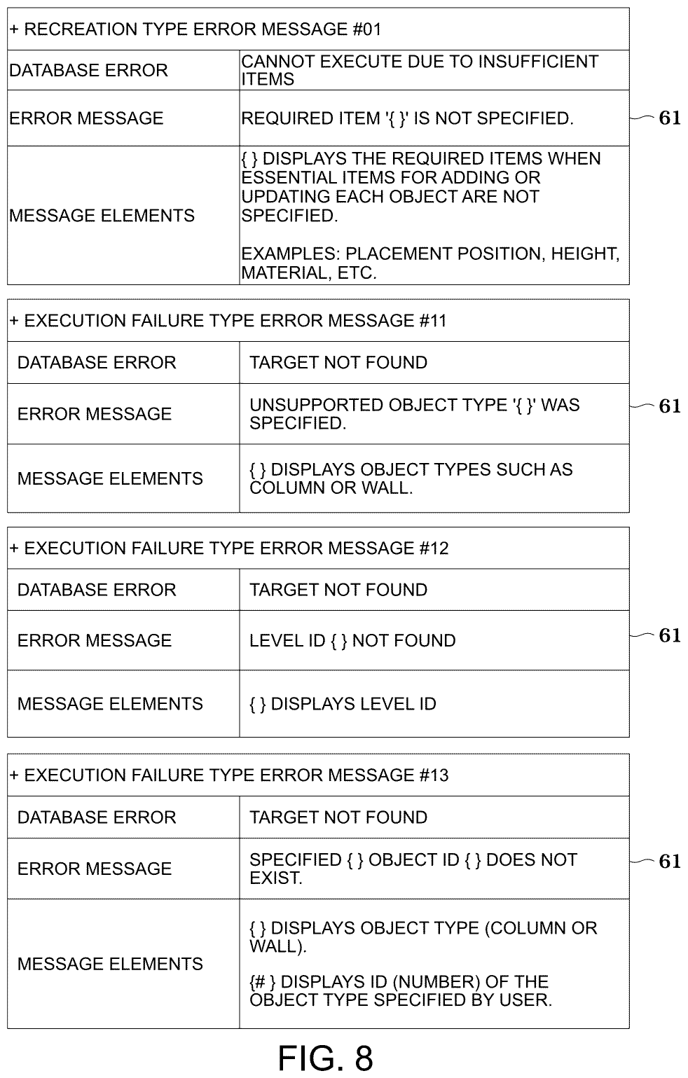

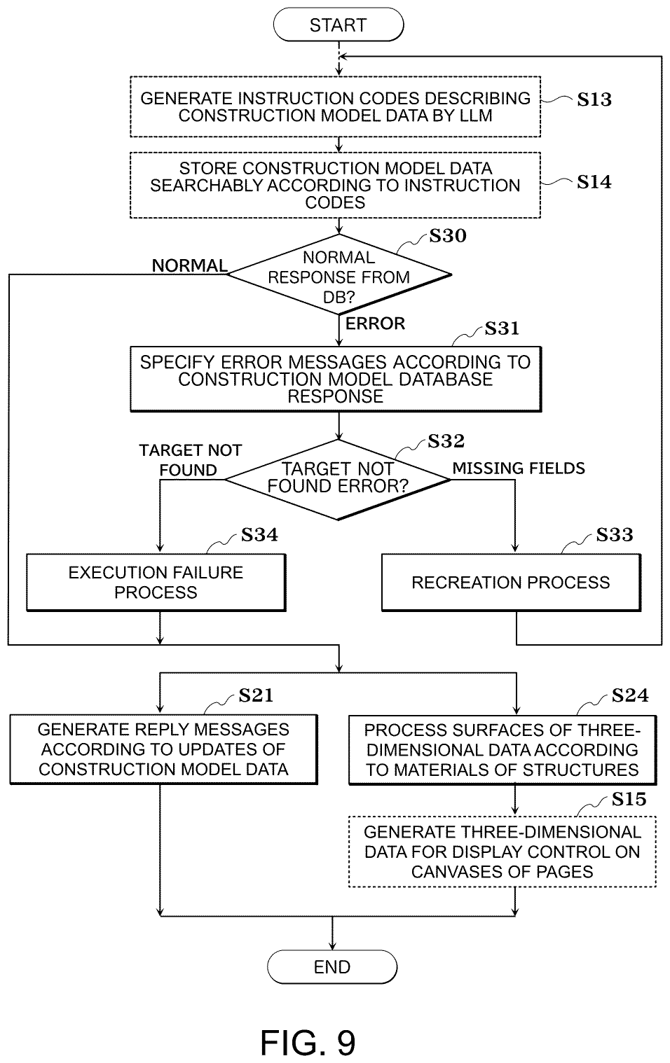

Instruction codes 31 may be executable codes that read JSON files, update targets, and output character strings that become JSON files again, or may be queries that update specific items in databases. The LLM unit 30 is a large language model with functions at the time of filing, and by providing the format of instruction codes 31 and construction model data 41 at startup, it can output instruction codes 31 corresponding to input messages 11 in natural language. Error processing when database operations by instruction codes 31 fail is disclosed in Embodiment 2 (for example, FIGS. 8 and 9).

In this embodiment, the LLM unit 30 (large language model) is treated as a commercially available component that converts input messages 11 in natural language into instruction codes 31. Converting natural language into code is an original function of large language models, and this embodiment is configured to generate instruction codes 31 for problem solving while implementing conditions specific to construction processes as data structures and processing content.

As respective innovations of each embodiment, for the LLM 30, toward generation of instruction codes 31, not only input messages 11 but also standard data 51, customized standard data 52, and conversation logs 71 in Embodiment 2, and design process data 54 in Embodiment 3 are read, proposing a configuration that enables creation of construction model data 41 that is consistent without excess or deficiency.

Controller 20 operates the construction model database 40.

Controller 20 executes operations (processing) on the construction model database 40 according to instruction codes 31 generated by the LLM unit 30 to realize requests of input messages 11 issued in natural language from users.

Specifically, the following operations are performed:
Data acquisition: Reads specific information from the database
Data addition (insertion): Adds new information to the database
Data update: Modifies existing information
Data deletion: Deletes unnecessary information from the database

These database operations are executed according to the data structure of construction model data 41 shown in FIG. 3.

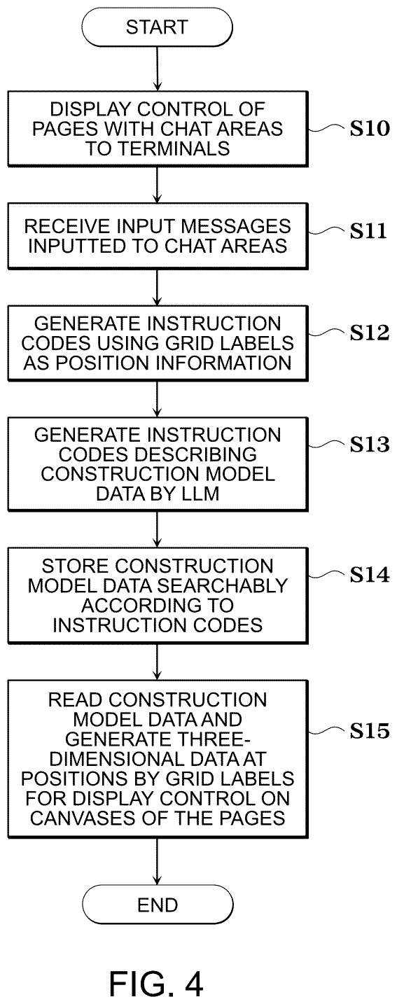

Referring to FIG. 4, the construction process support method of Embodiment 1 comprises a rendering processing step S10, an input message receiving step S11, a position information process step S12, a natural language processing step S13 (generation of instruction codes 31), a construction model data storage step S14, and a three-dimensional rendering process step S15.

Referring to FIG. 4, in the construction process support method of Embodiment 1, first, the rendering unit 10 controls display of pages 6 that serve as user interfaces connected to user terminals 2 (rendering processing step S10). Subsequently, the rendering unit 10 receives input messages 11 inputted as natural language data in chat areas 7 of pages 6 via network 4, and controls display of these input messages 11 in the chat areas 7 (input message receiving step S11). This input message receiving step S11 is part of the function of chat process 14 of controller 20.

Display in chat area 7 is preferably executed at timing after receiving input messages 11, before or after display of three-dimensional data 13, and before display of reply messages 12.

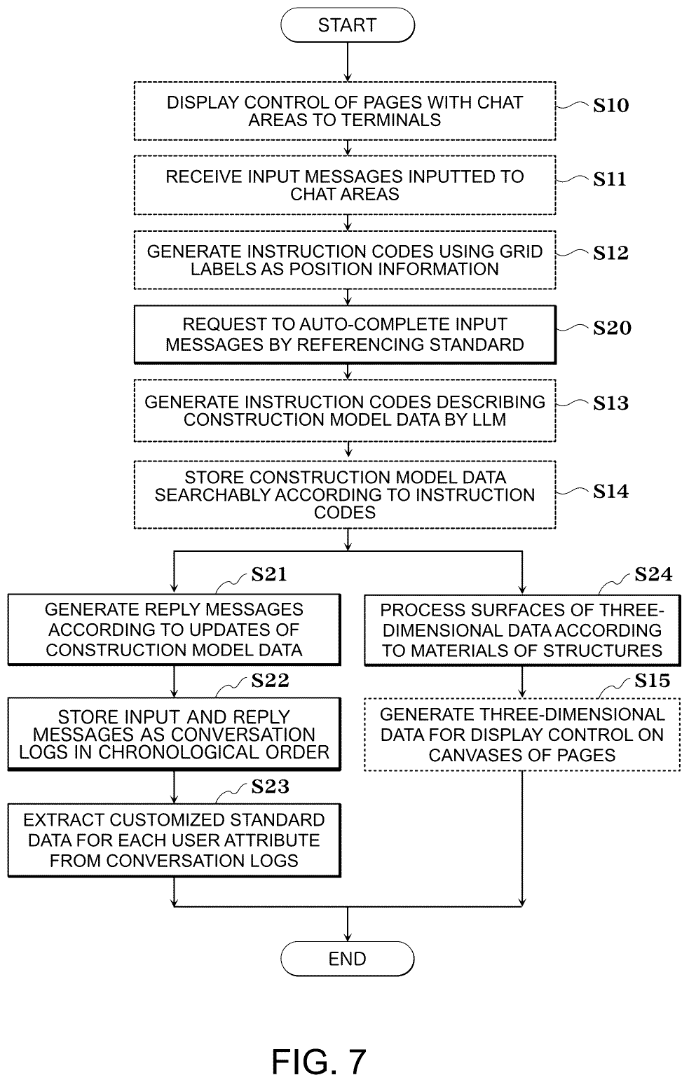

Note that in Embodiment 1, generation, display, and display control of reply messages 12 shown in FIGS. 5 and 7 are not essential.

When grid labels 21 that specify coordinates in canvas 8 within page 6 with character codes are included in input messages 11, controller 20 generates instruction codes 31 that use the grid labels 21 as position information of the structures (position information process step S12). Then, the LLM unit 30 refers to input messages 11 and generates instruction codes 31 that describe construction model data 41 through natural language processing. At this time, the LLM unit 30 specifies position information of structures to be described using grid labels 21 in input messages 11 (natural language processing step S13).

Subsequently, controller 20 executes instruction codes 31 to store construction model data 41 in construction model DB 40 in a searchable manner (construction model data storage step S14).

Subsequently, the rendering unit 10 converts construction model data 41 read from construction model DB 40 into three-dimensional data 13 and controls display on canvas 8. At this time, three-dimensional rendering process 15 generates three-dimensional data 13 of each structure at positions specified by grid labels 21 of each structure (three-dimensional rendering process step S15).

Each of these steps can be realized by having computer processors execute program groups (procedures) that operate computers as each step. In the embodiment, processing expressed as “steps” executes “procedures” by corresponding programs. Since disclosure of each step is also disclosure of procedures by programs executed by processors, overlapping disclosure of steps and procedures is omitted. However, in the disclosure of the embodiment, steps can be read as corresponding to procedures, and procedures can be read as corresponding to steps.

For example, the system and method of Embodiment 1 is a program executed by one or more computers, and can be implemented by a construction process support program that causes computers to execute a rendering processing procedure, an input message receiving procedure, a position information process procedure, a natural language processing procedure, a construction model data storage procedure, and a three-dimensional rendering process procedure.

Details of each procedure are the same as the disclosure of corresponding steps identified by name.

Additionally, processing for systems has correspondence with corresponding steps and procedures. For example, position information process 22 is step S12 shown in FIG. 4, and can be realized by executing a program for position information process procedures. However, processing is a system configuration where processing order is arbitrary, while steps and procedures differ in that they also have characteristics in processing order. Processing, steps, and procedures with the same name have commonality in roles to be performed in the entire system or entire method.

This relationship of processing, steps, and procedures is the same for Embodiments 2 to 4.

As described above, according to Embodiment 1, users can place structures on canvas 8 using natural language instructions and grid labels 21. Therefore, people unfamiliar with design, people unfamiliar with IT, design experts, and others can create construction model data 41 without learning complex operation methods. This can lower the barrier to introduction for input and storage of construction model data 41, which requires the most improvement in construction processes.

Additionally, since the LLM unit 30 generates instruction codes 31 using grid labels 21, construction model data 41 can be described with instruction codes 31 in defined formats while responding to diverse input messages 11 in natural language, maintaining consistency of construction model data 41.

Since three-dimensional data 13 is generated from construction model data 41 and display is controlled independently of the LLM unit 30, it is easy for users to visually confirm whether the content of construction model data 41 registered through interpretation of natural language input messages 11 is as intended.

Furthermore, since construction model DB 40 stores construction model data 41 in a searchable manner, in combination with LLM unit 30, reports and the like with accurate numbers and precision suitable for business use can be automatically generated.

Therefore, Embodiment 1 stores construction model data 41 in databases in a searchable manner while enabling design in natural language, providing a foundation for improving the work of many people involved in a series of processes including design to actual construction (work), subsequent maintenance of equipment and fixtures, building completion, and post-completion operation.

Thus, using the construction process support system, method, and program of Embodiment 1, users can create consistent construction model data 41 with only natural instructions.

### Embodiment 2

auto-complete process 23 of Embodiment 2

Referring to FIG. 5, the construction process support system of Embodiment 2 includes, in addition to the configuration of Embodiment 1, controller 20 equipped with auto-complete process (COMPLETION) 23, and rendering unit 10 equipped with surface process (SURFACE) 16.

In the example shown in FIG. 5, controller 20 is provided with a standard data table 50 that stores construction standard data 51.

Auto-complete process 23 causes the LLM unit 30 to refer to predetermined construction standard data 51 and complement construction model data 41 that is insufficient in input messages 11 regarding structures in the context corresponding to conversations with the user through natural language data. Then, the LLM unit 30 can include in instruction codes 31 content that is not included in input messages 11 but can be complemented by referring to standard data 51.

Surface process 16 processes surfaces of three-dimensional data 13 according to materials of structures specified by users or complemented, three-dimensional rendering process 15 of rendering unit 10 can specify textures of surfaces of three-dimensional data 13 according to materials (concrete, wood, etc.) of structures complemented by standard data 51 and render them on canvas 8. Therefore, users can visually confirm information about materials of structures that have been input or complemented.

For example, when receiving input data 11 under the premise of RC (reinforced concrete) construction, even if column materials are not specified, auto-complete process 23 specifies concrete as the column material from standard data 51 or conversation logs 71. Then, surface process 16 renders the surface with concrete texture as three-dimensional data 13. From the user's perspective, with minimal input, standard essential content is automatically complemented, and this can be easily confirmed visually with three-dimensional data 13 displayed on canvas 8, assuming there is conversational context with the system.

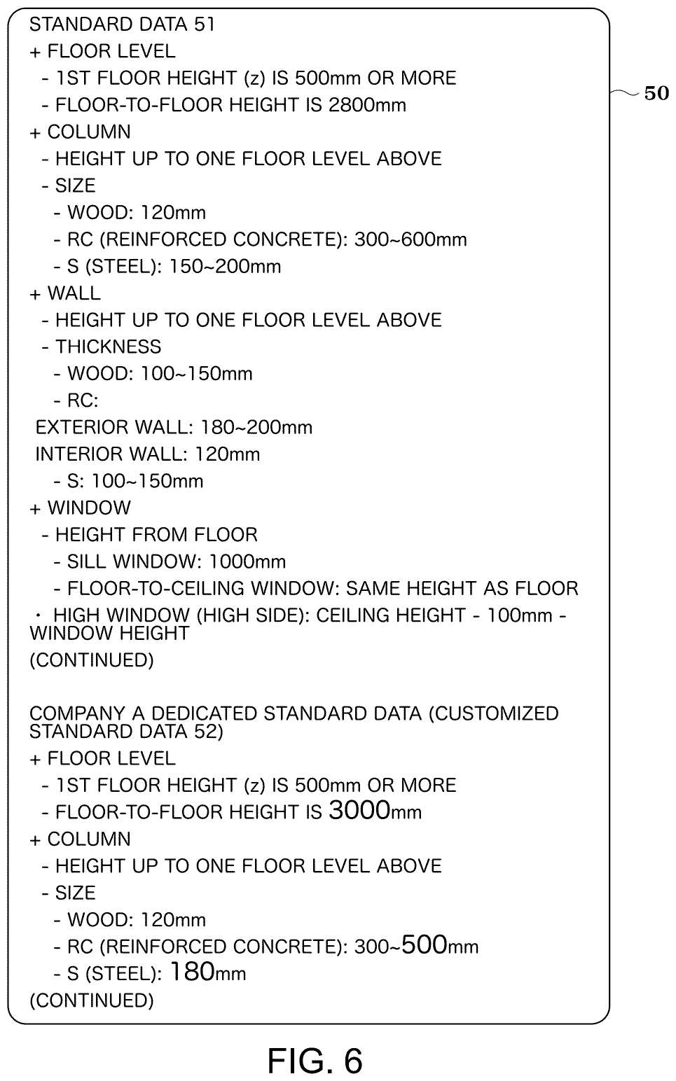

Referring to FIG. 6, the design standard data 51 of Embodiment 2 stores attributes such as conditions and sizes for each type of structure including floor levels, columns, walls, and windows.

By having auto-complete process 23 cause the LLM unit 30 to refer to this standard data 51, attributes (sizes, etc.) of structures not explicitly specified by users in input messages 11 can be complemented to generate instruction codes 31 that specify construction model data 41. For example, users can accumulate construction model data 41 including height information by only specifying column positions using grid labels 21 or relationships with existing structures, without specifying column heights.

In other words, this auto-complete process 23 can eliminate excess or deficiency in construction model data 41. By eliminating deficiencies through auto-complete process 23, minimal input is promoted and excessive detailed input is naturally suppressed.

Additionally, to enhance reliability of construction model data 41 by preserving design rationale and improve data maintainability, data items and values complemented according to control of auto-complete process 23 should be recorded as part of or in association with construction model data 41. Compared to conventional line drawings where what lines mean cannot be formally and uniquely interpreted, construction model data 41 can manage attribute data such as whether it is a living room or column. Furthermore, if it can be recorded that data items were complemented, not only the meaning of lines but also design rationale for how lines were selected can be recorded.

Additionally, when adopting general large language models available at the time of filing as the LLM unit 30, instruction codes 31 can be generated through auto-complete process 23 by providing content as shown in FIG. 6 as text files, without detailed coding. While fine-tuning may be performed before startup of the entire construction process support system, using a method where controller 20 inputs standard data 51 as text data along with usage instructions to the LLM unit 30 when starting up the LLM unit 30 via API enables utilization of the latest standard data 51.

Since auto-complete process 23 specifies materials of structures according to conversational context, and surface process 16 automatically specifies colors and textures of structure surfaces in three-dimensional data 13 according to materials without user specification, users can confirm whether the design is as intended with three-dimensional data 13 that includes complemented content and has three-dimensional, color, and material texture close to the completed image. Therefore, overall consistent design can be achieved with only minimal instructions.

In the configuration of Embodiment 2, through organic combination of auto-complete process 23 using standard data 51 and surface process 16, users can create construction model data 41 without excess or deficiency through natural language dialogue.

In other words, users can create standard construction model data 41 while confirming with three-dimensional data 13 by simply providing minimal instructions in natural language text or voice in chat area 7 of Embodiment 2. This is a result that cannot be achieved simply by using large language models, and is a result that can be realized by a new system configuration that combines elemental technologies such as rendering unit 10, controller 20, position information process 22, auto-complete process 23, standard data 51, and configurations that cause the LLM unit 30 to generate instruction codes 31 as shown in FIG. 5.

Customized Standard Data 52 of Embodiment 2

Referring again to FIG. 5, the construction process support system of Embodiment 2 preferably includes a conversation log database 70. In this example, controller 20 includes reply process (REPLY) 24 and Extraction process (EXTRACTION) 25.

Reply process 24 causes the LLM unit 30 to generate reply messages 12 to users related to update content in response to updates of construction model data 41 to construction model database 40.

Conversation log database 70 stores time-series data of input messages 11 and reply messages 12 as conversation logs 71.

Extraction process 25 causes the LLM unit 30 to refer to conversation logs 71 and extract customized standard data 52 for each user attribute according to the configuration of the standard data 51.

In this example, auto-complete process 23 preferably applies customized standard data 52 for each user or organization to which users belong with priority over general standard data 51.

Reply process 24 may control display of reply messages 12 that explain current offset amounts in chat area 7, for example, when both offset amounts for each grid label 21 and collective offset amounts for multiple grid labels 21 such as living rooms are registered as offset amounts of construction model data 41. By being able to explain the content of construction model data 41 through this reply process 24, users can be naturally informed of how construction model data 41 is registered, including complemented content, in integration with display of three-dimensional data 13.

As shown in FIG. 6, standard data table 50 preferably stores Company A dedicated standard data as customized standard data 52. Customized standard data 52 has the same set as standard data 51 while numerical values are overwritten. For example, while floor level height is 2800 [mm] in standard data 51, it is overwritten to 3000 [mm] in Company A dedicated data. Additionally, customized standard data 52 may have items not present in standard data 51. In the example that has the customized standard data 52, the completion process 23 auto-completes the construction model data 41 by referencing the customized standard data 52 as or similarly to the standard data 51.

Embodiment 2 utilizing this customized standard data 52 includes conversation log database 70, and Extraction process 25 extracts customized standard data 52. Therefore, standard data regarding design and construction processes for individual users, companies or departments to which users belong, or individual projects can be extracted from past conversation logs.

Particularly when customized standard data 52 includes numerical values, rather than having the LLM unit 30 perform additional learning, organizing as customized standard data 52 enables control of complementation through natural language conversation without fluctuation, and can stabilize operation and performance of the entire system at high levels while using large language processing models.

By making customized standard data 52 text data in natural language as shown in FIG. 6, it can be handled as manuals that are easy to understand for both the LLM unit 30 and users. For usage by users and their organizations, customized standard data 52 may be extracted and approved in internal meetings, with confirmed content stored in standard data table 50.

As design rationale, if it can be recorded whether input is from users, standard data 51, or customized standard data 52, traceability of design decisions can be dramatically improved, and reasons can be shared throughout construction processes.

Customized standard data 52 is customized for each company based on standard data 51 (basic manual) and directly contributes to productivity improvement for each company. Standard data 51 and customized standard data 52 are referenced when complementing dimensions when there are no detailed instructions from users. This is not limited to complementation only, and can also be used as reference data when proposing dimensions to users.

In Embodiment 2, since customized standard data 52 can be utilized, design can be prevented from becoming person-dependent, dimensional standards can be unified for each organization, entire construction processes can be standardized, waste can be eliminated, productivity can be enhanced, and stress on working people can be reduced.

Detailed examples of standard data 51 and customized data 52 shown in FIG. 6 are disclosed. The hierarchical structure follows the order of ‘+’, ‘-’, -’. Numerical values overwritten in customized standard data 52 are indicated with double brackets “(( )”. Company A { } dedicated manual is customized standard data 52 for special projects.

When numerical values have ranges, the ranges may be shown to users to prompt input, or the LLM unit 30 may be caused to select values consistent with other structures within those ranges. In any case, when contradictions are visually identified in three-dimensional data 13, they are updated by users, and when there is refresh processing or review processing of construction model data 41, consistency confirmation processing between structures may be executed.

### Standard Data 51

+Floor Level
−First floor height (z) is 500 mm or more
−Floor-to-floor height is 2800 mm
+Column
−Height up to one floor level above
−Size
−Wood: 120 mm
   −RC (reinforced concrete): 300-600 mm
   −S (steel): 150-200 mm
+Wall
−Height up to one floor level above
−Thickness
   −Wood: 100-150 mm
   −RC construction
      Exterior wall: 180-200 mm
      Interior wall: 120 mm
−S construction: 100-150 mm
+Window
−Height from floor
   −Waist-high window: 1000 mm
   −Floor-to-ceiling window: Same height as floor surface
   −High window (high side): Ceiling height−100 mm−window height
−Window height itself
   −Waist-high window: 1100 mm
   −Floor-to-ceiling window: 2000 mm
   −High window: 300, 450, or 600 mm
−Window width itself
   −Waist-high window: 1650 mm
   −Sliding window: 1690 mm
   −Floor-to-ceiling window: 1500-2600 mm
+Door
−Height
   −Entrance door: 2000-2400 mm
   −Interior door: 1800-2000 mm
−Width
   −Entrance door: 780-900 mm
      Parent-child door or double door: 1220-1690 mm
   −Interior door: 700-800 mm
      Toilet door: 600 mm
+Curtain Wall
−Glass thickness
   −6-12 mm
+Floor
−Thickness (height)
   −15 mm
+Handrail
−Height
   −1100 mm

Company A Dedicated Manual (Customized Standard Data 52)
+Floor Level
−First floor height (z) is 500 mm or more
−Floor-to-floor height is ((3000)) mm
+Column
−Height up to one floor level above
−Size
   −Wood: 120 mm
   −RC (reinforced concrete): 300−((500)) mm
   −S (steel): ((180)) mm
+Wall
−Height up to one floor level above
−Thickness
   −Wood: 100-150 mm
   −RC construction
      Exterior wall: 180-200 mm
      Interior wall: ((150)) mm
−S construction: ((120)) mm
+Window
   −Height from floor
      −Waist-high window: ((900)) mm
      −Floor-to-ceiling window: Same height as floor surface
      −High window (high side): Ceiling height−((150))mm−window height
−Window height itself
   −Waist-high window: 1100 mm
   −Floor-to-ceiling window: 2000 mm
   −High window: 300, 450, or 600 mm
   −Window width itself
   −Waist-high window: 1650 mm
   −Sliding window: 1690 mm
   −Floor-to-ceiling window: 1500-2600 mm
+Door
−Height
   −Entrance door: 2000-2400 mm
   −Interior door: 1800-2000 mm
Width
   −Entrance door: 780-900 mm
Parent-child door or double door: 1220-1690 mm
   −Interior door: 700-800 mm
+Curtain Wall
−Glass thickness
   −((10)) mm
+Floor
−Thickness (height)
   −15 mm
+Handrail
−Height
   −((1200)) mm

Company A { } Dedicated Manual (Customized Standard Data 52)
+Floor Level
−First floor height (z) is 500 mm or more
−Floor-to-floor height is ((2900)) mm
+Column
−Height up to one floor level above
−Size
   −Wood: 120 mm
   −RC (reinforced concrete): 300-((500)) mm
−S (steel): ((180)) mm
+Wall
−Height up to one floor level above
−Thickness
   −Wood: 100-150 mm
   −RC construction
      Exterior wall: 180-200 mm
      Interior wall: ((150)) mm
−S construction: ((120)) mm
+Window
−Height from floor
   −Waist-high window: ((800)) mm
   −Floor-to-ceiling window: Same height as floor surface
   −High window (high side): Ceiling height−((120)) mm−window height
−Window height itself
   −Waist-high window: 1100 mm
   −Floor-to-ceiling window: 2000 mm
   −High window: 300, 450, or 600 mm
   −Window width itself
   −Waist-high window: 1650 mm
   −Sliding window: 1690 mm
   −Floor-to-ceiling window: 1500-2600 mm
+Door
−Height
   −Entrance door: 2000-2400 mm
   −Interior door: 1800-2000 mm
−Width
   −Entrance door: 780-900 mm
   −Parent-child door or double door: 1220-1690 mm
−Interior door: 700-800 mm
+Curtain Wall
−Glass thickness
   (−(12)) mm
+Floor
−Thickness (height)
   −15 mm
+Handrail
−Height
   −1100 mm

Construction Process Support Method of Embodiment 2 (Auto-complete Process 23, Customized Standard Data 52)

Referring to FIG. 7, the construction process support method of Embodiment 2 newly includes, in addition to the configuration of the construction process support method of Embodiment 1 shown in FIG. 4, an auto-complete process step S20, a reply process step S21, a conversation log recording processing step S22, an Extraction process step S23, and a surface process step S24.

Content similar to the steps and procedures shown in FIG. 4 of Embodiment 1 is indicated by dotted lines in FIG. 7.

Referring to FIG. 7, in the construction process support method of Embodiment 2, similar to Embodiment 1 (FIG. 4), the rendering unit 10 controls display of page 6 (rendering processing step S10), receives input messages 11 inputted as natural language data in chat area 7 of page 6, and controls display in chat area 7 (input message receiving step S11). When grid labels 21 are included in input messages 11, controller 20 generates instruction codes 31 that use the grid labels 21 as position information of the structures (position information process step S12).

Particularly in Embodiment 2, auto-complete process 23 causes the LLM unit 30 to refer to standard data 51 and complement construction model data 41 that is insufficient in input messages 11 regarding structures in the context corresponding to conversations with the user through natural language data (auto-complete process step S20). Then, the LLM unit 30 refers to input messages 11 and generates instruction codes 31 that describe construction model data 41 through natural language processing, and particularly in Embodiment 2, adds numerical values of items that exist in standard data 51 but are not in input messages 11 received so far as auto-complete process 23 (natural language processing step S13).

Subsequently, controller 20 executes instruction codes 31 to store construction model data 41 in construction model DB 40 in a searchable manner (construction model data storage step S14).

Chat process 14 of rendering unit 10 controls display of input messages 11 in chat area 7 (input message receiving step S11). In Embodiment 2, reply process 24 of controller 20 generates reply messages 12 to users related to update content in response to updates of construction model data 41 to construction model DB 40 (reply process step S21).

The LLM unit 30 generates reply messages 12 in natural language based on execution results of instruction codes 31. For example, sentences such as “{ } has been placed at the grid label position.”

In Embodiment 2, controller 20 saves input messages 11 and reply messages 12 in conversation log database 70 in chronological order (conversation log recording processing step S22). Then, Extraction process 25 of controller 20 extracts customized standard data 52 from conversation logs 71 for each user attribute according to the configuration of standard data 51. For example, controller 20 may have the LLM unit 30 read conversation logs 71 and request generation of content that overwrites values of standard data 51 or items that are not in standard data 51 but are additionally included as customized standard data 52.

Additionally, in Embodiment 2, surface process 16 processes surfaces of three-dimensional data 13 according to materials of structures specified by users or complemented (surface process step S24). For example, surfaces of three-dimensional data 13 of structures are rendered with textures corresponding to material names of structures (objects). Then, three-dimensional rendering process 15 generates three-dimensional data 13 of each structure at positions specified by grid labels 21 of each structure (three-dimensional rendering process step S15).

As shown in FIG. 7, customized standard data 52 can be immediately used in the next input message 11 when extracted from conversation logs and updated for each input of input messages 11. On the other hand, to ensure greater stability as standards, conversation logs 71 may be read at the time of floor design completion or overall construction model design completion to extract content that overwrites items in standard data 51 and content that is not in standard data 51 items but is particularly repeatedly specified in input messages 11.

### Embodiment 2: Error Messages 61

Next, an example of using error messages 61 in Embodiment 2 is disclosed.

Referring again to FIG. 5, regarding error processing, the construction process support system of Embodiment 2 includes an error message table 60 alongside controller 20. Controller 20 includes recreation process 26 and execution failure process 27.

Error message table 60 stores error messages 61 in advance. Error messages 61 are messages in natural language data that point out insufficient specification of data items or non-existence of targets by instruction codes 31 regarding errors in execution results of instruction codes 31. Instruction codes 31 are codes generated by the LLM unit 30 from input messages 11 and the like according to control by controller 20.

Recreation processing 26 causes the LLM unit 30 to refer to the error messages 61 and recreate the instruction codes 31 when execution results of instruction codes 31 are errors of insufficient specification of data items.

On the other hand, the execution failure process 27 displays the error message 61 on page 6 when the execution result of the instruction code 31 is an error due to the non-existence of a target.

Insufficient specification of data items applies, for example, when column positions are required but not specified. Non-existence of targets applies when columns with IDs to be deleted are not registered in construction model database 40.

The execution results of the instruction codes 31 are operation results from the construction model database 40. The operation results are results obtained from the database after the controller 20 operates the construction model database 40 according to the instruction codes 31. The controller 20 branches error processing according to the operation results. The database operation results are important information for generating reply messages to user requests and for performing database operations stably and appropriately. In embodiment 2, the controller 20 references error codes that the construction model database 40 outputs as normal functions and identifies error messages 61 that are pre-created in natural language.

Referring to FIG. 8, error messages 61 of Embodiment 2 are divided into two types: recreation type and execution failure type.

The recreation type occurs when required items are not specified and are not complemented even after auto-complete process 23 by referring to standard data 51.

Error messages 61 are formatted as “Required item ‘{ }’ is not specified,” etc. These error messages 61 are not error codes output by construction model DB 40, but are error messages 61 predetermined according to error codes.

In the { } of error messages 61, items required for adding or updating each structure (object) are displayed. For example, placement position, height, material, etc. In other words, even when users do not specify details in input messages 11, the LLM unit 30 complements according to control from controller 20, but errors occur when the LLM unit 30 fails to complement.

For example, when placement position and material are included in instruction codes 31 but height is not included in instruction codes 31, generating instruction codes 31 again with this recreation type error enables the LLM unit 30 to generate instruction codes 31 by complementing from standard data 51.

For important items such as placement position where it is fundamentally unclear where to place, it is advisable to inquire with users as execution failure type errors.

In Embodiment 2, error messages 61 are created by classifying them in advance as either recreation type or execution failure type according to structure (object) types while also referring to items in standard data 51. By making this two-category classification, repeated posing of unsolvable questions to the LLM unit 30 can be suppressed while minimizing items that users must specifically specify, thereby enabling robust and effective construction process support.

As an execution failure type, error message 61 of #11 is “Unsupported object type ‘{ }’ was specified.” In { }, object types such as column or wall are displayed.

This error occurs when unsupported object types are specified in instruction codes 31 by the LLM unit 30. The LLM unit 30 generates reply messages 12 that inform users that the object is not supported.

Error message 61 of #12 is “Level with ID { } not found,” and the level (floor) ID is displayed in { }.

For example, ground level is ID0, first floor level is ID1, etc., and unique IDs are automatically assigned by controller 20 or construction model DB 40.

When users specify a floor (level) that does not yet exist when installing some new object, this #12 error occurs.

For example, when the third floor is not yet set and input message 11 from the user is “Please add a column to C3 on the third floor level,” processing proceeds as follows:

[1] The LLM unit 30 or controller 20 confirms what ID number corresponds to the floor (third floor) level specified by the user.

[2] Then, when controller 20 determines that the specified floor level does not yet exist, it transmits error message 61 “Level with ID3 not found” to the LLM unit 30 and causes the LLM unit 30 to generate reply message 12.

The LLM unit 30 generates reply message 12 such as “The third floor level has not been set yet, so columns cannot be placed.”

Additionally, when the LLM unit 30 infers level IDs from conversational context with users, it may generate instruction codes 31 that include non-existent level IDs. In this case, controller 20 similarly generates error #12. When controller 20 transmits error message 61 “Level with ID3 not found” to the LLM unit 30 and generates reply message 12, even if inference errors (hallucination) by the large language model (LLM unit 30) occur, inconsistencies in construction model data 41 are not generated, and design using natural language input messages 11 can continue within the normal range.

Error message 61 of #13 is “Object ID {#} of the specified { } does not exist.

In the first { }, object types (column or wall) are displayed.

In {#}, the ID (number) of that object type specified by the user is displayed.

For example, this is an error when the specified object ID does not exist when deleting or updating some existing object.

For example, when input message 11 from the user is “Please delete column ID100,” this error occurs if column with ID100 does not exist.

The LLM unit 30 generates instruction code 31 to delete column with ID100, and controller 20 executes instruction code 31. Then, construction model DB 40 returns an error code indicating that the object does not exist because column with ID100 does not exist. Controller 20 transmits this #13 error message 61 to the LLM unit 30 regarding this object non-existence error code.

Then, the LLM unit 30 generates reply message 12 such as “Column with ID100 does not exist.” When the target does not exist, controller 20 may directly control display of error message 61 as reply message 12 in chat area 7, but when error message 61 is transmitted to the LLM unit 30, the LLM unit 30 generates reply message 12 including error message 61 according to context, and may also generate suggestions for what should be done next regarding error message 61.

When users specify objects not by ID but by floor and grid labels 21, such as “column at C3 on the third floor,” and instruct movement or deletion, if that C3 column does not exist, it similarly results in #12 error processing.

In Embodiment 2, errors are classified into those with possibility of normal completion without additional information from users and those without such possibility. When there is possibility of normal completion, recreation of instruction codes 31 is requested from the LLM unit 30, and when there is no possibility of normal completion, users are notified of errors regarding target non-existence.

By creating error messages 61 to enable this classification and storing them in error message table 60 in advance, robust systems can be realized for diverse input messages 11 without depending on the capabilities of the LLM unit 30.

Referring to FIG. 9, the construction process support method of Embodiment 2 that processes error messages 61 newly includes, following construction model data storage step S14 of the construction process support methods shown in FIG. 4 of Embodiment 1 and FIG. 7 of Embodiment 2, response determination processing step S30, error message identification processing step S31, error classification processing step S32, recreation processing step S33, and non-existence processing step S34.

As shown in FIG. 9, similar to Embodiment 1, the LLM unit 30 refers to input messages 11 and generates instruction codes 31 that describe construction model data 41 through natural language processing. At this time, in Embodiment 2, as auto-complete process 23, numerical values of items that exist in standard data 51 but are not in input messages 11 received so far are added as auto-complete process 23 (natural language processing step S13).

Subsequently, controller 20 executes instruction codes 31 to store construction model data 41 in construction model DB 40 in a searchable manner (construction model data storage step S14).

In Embodiment 2 that processes error messages 61, controller 20 confirms processing results (response codes or error codes) from construction model database 40 and determines whether they are normal responses (response determination processing step S30). When addition operations, update operations, deletion operations, etc. are successful, processing proceeds to the processing described as Embodiments 1 and 2 (S21, S24) as normal responses. In the example shown in FIG. 9, when the response is not normal, error messages 61 shown in FIG. 8 are identified by referring to error codes, etc. (error message identification processing step S31).

When execution results of instruction codes 31 are errors of insufficient specification of data items (error classification processing step S32), the LLM unit 30 is caused to refer to the error messages 61 and recreate the instruction codes 31 (recreation processing step S33). Returning to step S13, the LLM unit 30 identifies insufficient specification content from error messages 61, generates instruction codes 31 again (S13), and controller 20 executes the recreated instruction codes 31 (S14).

When these recreated instruction codes 31 do not complete normally (S30), controller 20 preferably determines them as target non-existence type errors (S32).

In step S32, when execution results of instruction codes 31 are target non-existence errors either initially or as a result of loops (S32), error messages 61 notifying target non-existence are displayed on page 6 (non-existence processing step S34). Controller 20 may directly control display of these target non-existence error messages 61 in chat area 7, or may pass error messages 61 to the LLM unit 30 once and have the LLM unit 30 generate reply messages 12 including error messages 61 (S21).

Recreation processing 26 shown in FIG. 5 corresponds to steps S31, S32, S33 to S13 in the example shown in FIG. 9, execution failure process 27 shown in FIG. 5 corresponds to steps

S31, S32, S34, S21 in the example shown in FIG. 9.

### Embodiment 3

Referring to FIG. 10, in the construction process support system of Embodiment 3, controller 20 includes input promotion processing 28. Additionally, standard data table 50 stores design process data 54 predetermined as standard design processes.

Input promotion processing 28 reads design process data 54 from standard data table 50, causes the LLM unit 30 to refer to it, and causes the LLM unit 30 to generate reply messages 12 that prompt input of content to be designed following the state of construction model data 41.

Design process data 54 is a proceduralized version of textbook-like design content.

Within the scope of explanation for Embodiment 3, it includes, for example, the order of decisions in design such as construction method selection, floor level setting, floor plan (structure placement and human traffic flow), columns, doors, and windows.

In Embodiment 3, defining standard design sequences as design process data 54 for elements of construction model data 41 (types of structures) proceeds smoothly.

Additionally, when construction methods such as steel reinforced concrete construction, reinforced concrete construction, conventional wooden post-and-beam construction, or wooden frame wall construction (two-by-four construction) are specified, standards for materials of columns and walls can be identified.

By defining construction methods in standard data 51 and design process data 54 and having the LLM unit 30 refer to these data, even when materials are not specified in input messages 11, concrete materials can be complemented when generating columns.

In Embodiment 3, by having the LLM unit 30 refer to design process data 54 to generate reply messages 12, it can generate both reports of execution results (“Living room has been registered”) and suggestions for items to input next (“Where would you like to place the kitchen?”).

By configuring input promotion processing 28 to generate reply messages 12 through reference to design process data 54 rather than additional learning by the LLM unit 30, deviation of reply messages 12 from construction model data 41 to be designed can be prevented, and consistency of construction model data 41 can continue to be ensured.

The construction process support method equipped with input promotion processing 28 of Embodiment 3 preferably newly includes input promotion processing step S40 integrally with or following reply process step S21 shown in FIGS. 4, 7, and 9 (not shown).

Referring again to FIG. 7, when construction model data 41 is stored in construction model DB 40 using instruction codes 31 generated by the LLM unit 30 in step S14, subsequently, reply process 24 generates reply messages 12 according to the latest situation where storage or updating of construction model data 41 was successful (S21). In Embodiment 3, input promotion processing 28 refers to design process data 54 and generates reply messages 12 that prompt input of content to be designed following the current state of construction model data 41 (S40, not shown).

For example, by specifying in design process data 54 the sequence of prompting kitchen design following living room, and column and window design when the floor plan of one floor is determined, the LLM unit 30 can be caused to generate reply messages 12 that suggest what should be input next.

For reply message 12, a format such as “{ } placed. Please confirm. Next, where would you like to place { }?” is recommended.

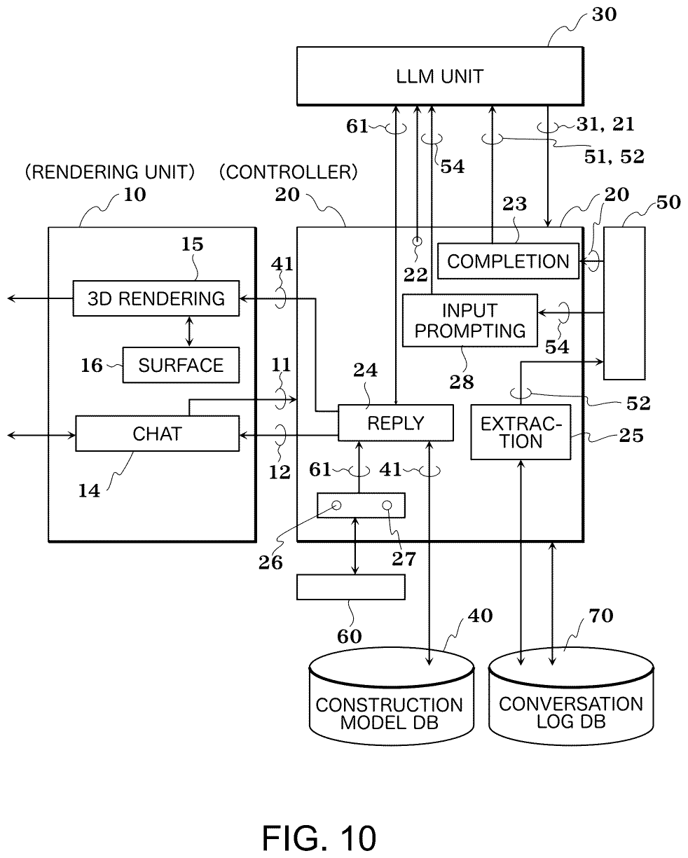

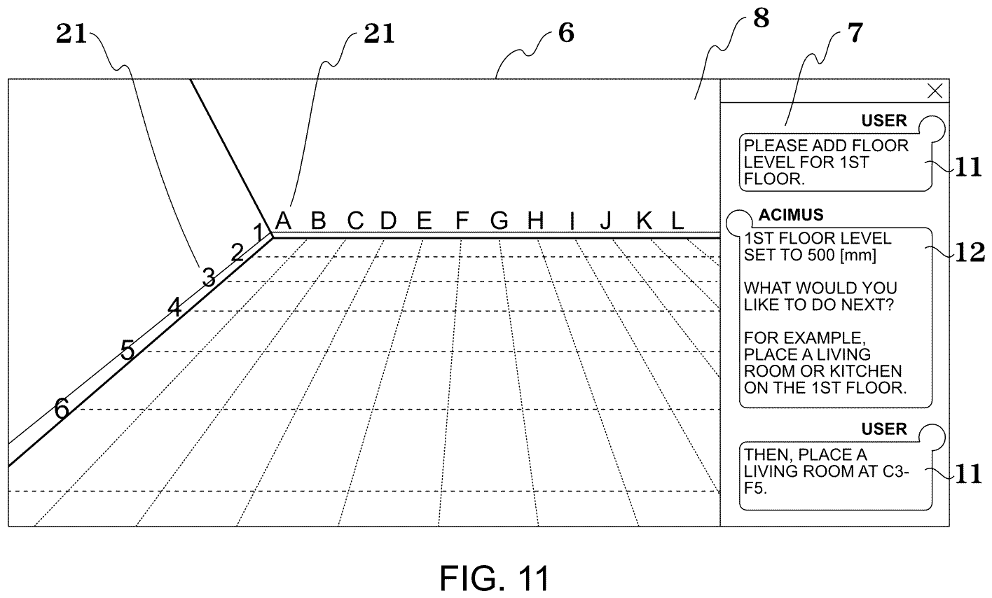

Next, referring to FIGS. 11 to 16, specific processing examples in Embodiment 3 are shown. This content has parts in common with Embodiments 1 and 2.

Case: Addition of floor levels and placement of zones and columns

Assuming RC (reinforced concrete) apartment buildings

As design process data 54, in this example, for simplicity of explanation, procedures for installing columns after placing living rooms are described virtually. In practice, procedures for placing columns after placing zone objects such as living rooms and kitchens are preferable.

In this embodiment, the system name that is the speaker of reply messages 12 is “ACIMUS.”

Addition (creation) of floor level

User: “PLEASE ADD FLOOR LEVEL FOR 1ST FLOOR.”

System (ACIMUS): “1ST FLOOR LEVEL SET TO 500 [mm]′ “WHAT

WOULD YOU LIKE TO DO NEXT? FOR EXAMPLE, PLACE A LIVING ROOM OR KITCHEN ON THE 1ST FLOOR.”

Addition (creation) of zone objects

User: “THEN, PLACE A LIVING ROOM AT C3-F5.” (FIG. 11 chat area 7)

System (ACIMUS): “THEN, PLACE A LIVING ROOM AT C3-F5.

NEXT, WHAT WOULD YOU LIKE TO PLACE AT THE LIVING ROOM CORNERS?

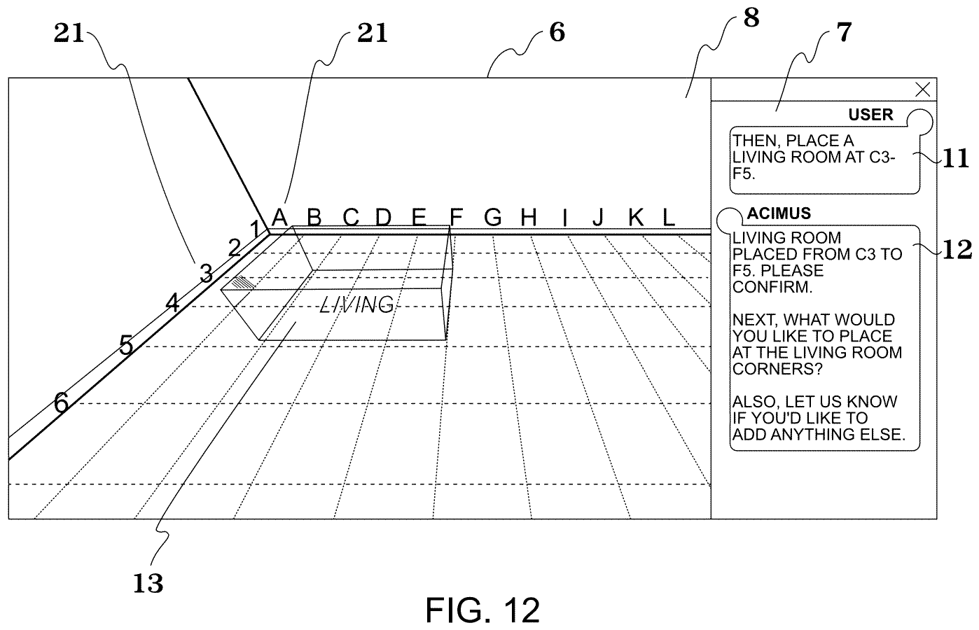

ALSO, LET US KNOW IF YOU'D LIKE TO ADD ANYTHING ELSE.” (FIG. 12)

Change (update) of zone objects

User: “CHANGE THE LIVING ROOM TO POSITION D3˜G5.”

System: “THE LIVING ROOM HAS BEEN MOVED TO D3˜G5. PLEASE CHECK.

WOULD YOU LIKE TO ADD COLUMNS AT THE LIVING ROOM CORNERS NEXT?”

Addition (creation) of column objects

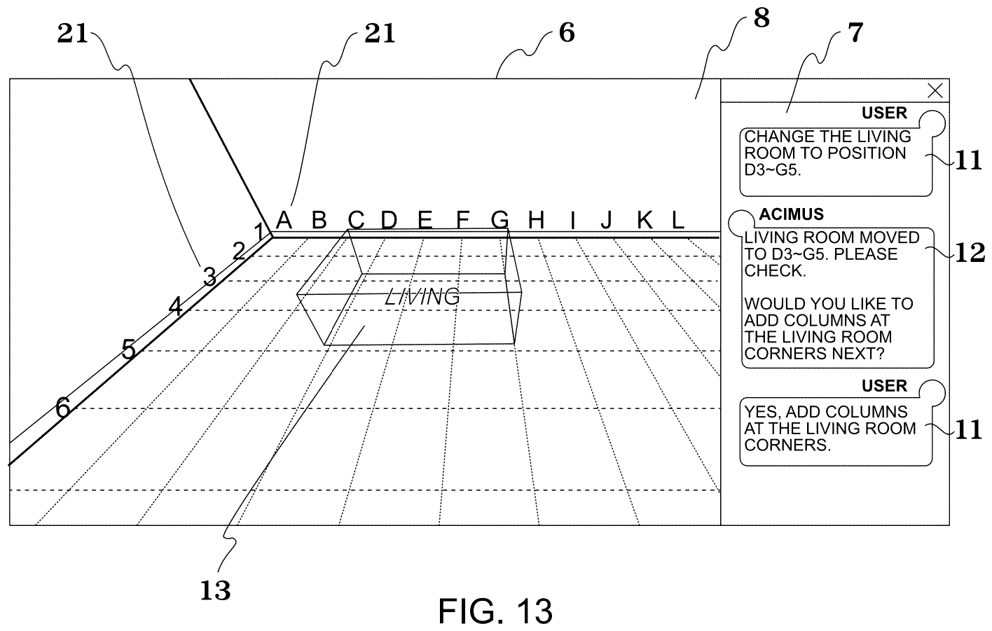

User: “YES, ADD COLUMNS AT THE LIVING ROOM CORNERS.” (FIG. 13)

“System: “ ” COLUMNS PLACED AT LIVING ROOM CORNERS. PLEASE CHECK.” “NEXT,

HOW ABOUT PLACING 200 MM WIDE WALLS BETWEEN COLUMNS?”

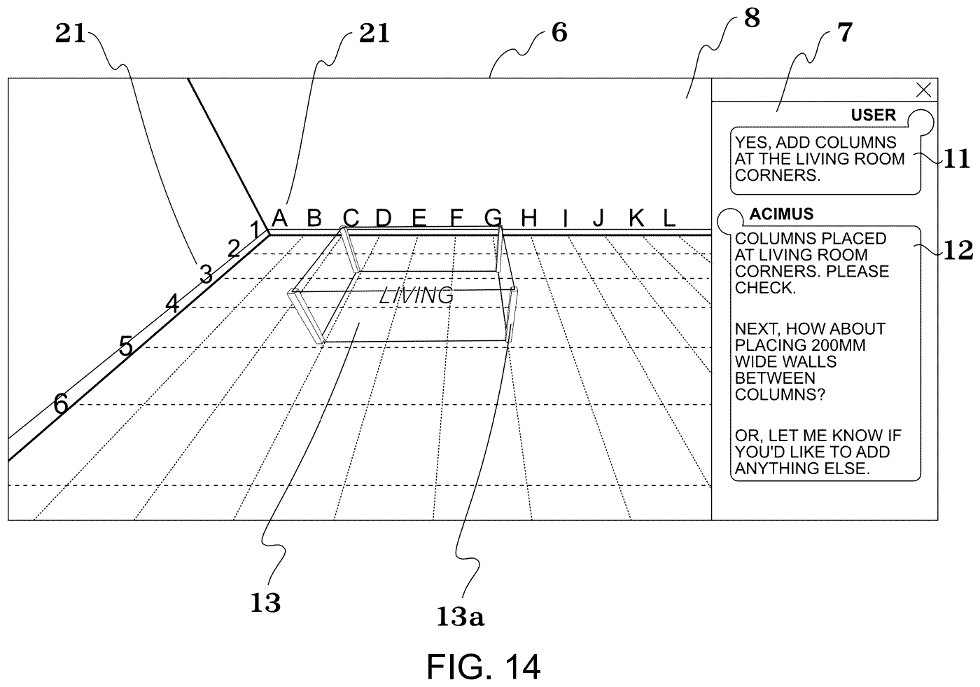

OR, LET ME KNOW IF YOU'D LIKE TO ADD ANYTHING ELSE.” (FIG. 14)

Reading column objects

User: “HOW MANY COLUMNS ARE THERE?”

System:
“1.
D3
2. D5
3. G3
4. G5

ANYTHING ELSE TO CHANGE?

Deletion of column objects

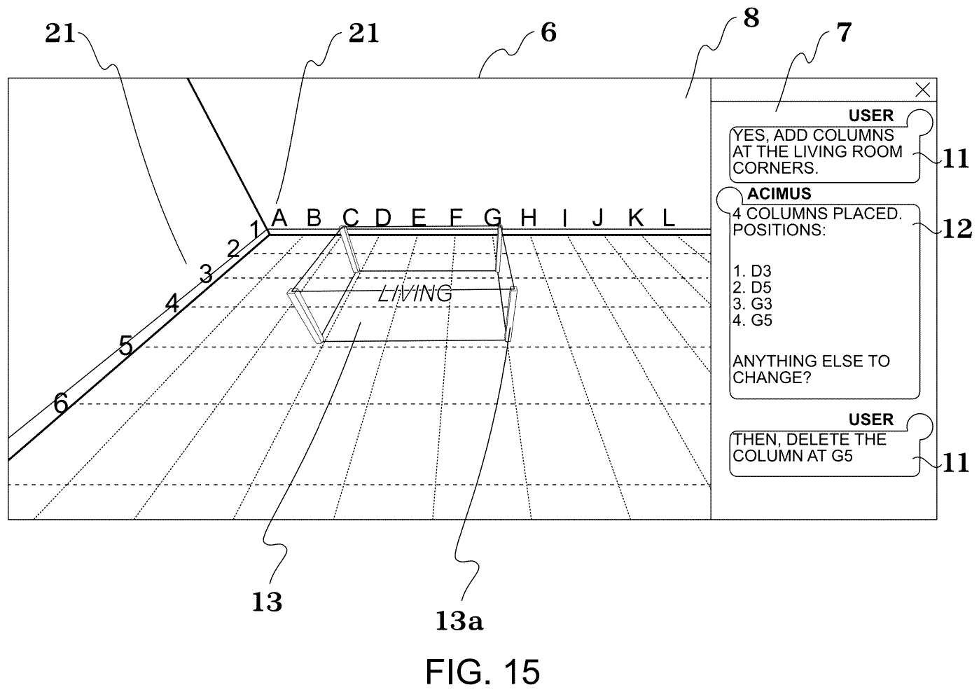

User: “THEN, DELETE THE COLUMN AT G5.” (FIG. 15)

System: “THE COLUMN AT G5 HAS BEEN DELETED. IS THERE ANYTHING ELSE YOU

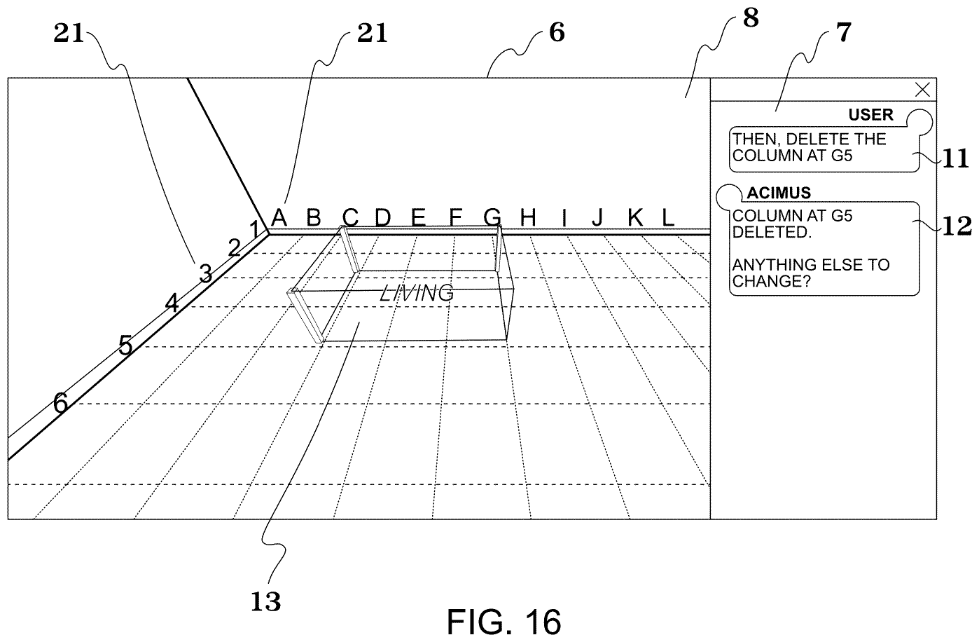

WOULD LIKE TO CHANGE?” (FIG. 16)

The three-dimensional data 13 with reference numeral 13a shown in FIG. 15 is the column at G5 identified by grid label 21, and is deleted as shown in FIG. 16. Column identification may be performed using grid labels 21, or by adding column ids shown in FIG. 3 through three-dimensional rendering process 15 and controlling display on canvas 8 while identifying and interacting using those id numbers.

In Embodiment 3, since the LLM unit 30 grasps the living room position from the previous exchange, columns can be placed at D3, D5, G5, and G3 where they should be placed simply by communicating “corners of the living room.”

Additionally, suggestions for what to do next are provided in reply messages 12.

Furthermore, even without specifying specific floor level heights or column sizes and heights, the system auto-completes general dimensions for structures (numerical values in standard data 51) as the dimensions of the structure.

Thus, in this embodiment, addition, modification, reading, and deletion of consistent structures (objects) without excess or deficiency is possible through natural language conversation.

In this regard, simply using large language models cannot display three-dimensional data 13 (3D objects) on canvas 8, and it is difficult to execute coordinates without misunderstanding between users and systems (large language models). Furthermore, when context and premises arise between users and systems and coordinate values are expressed in natural language with special expressions, construction model data 41 cannot be constructed consistently.

In this embodiment, first, by using grid labels 21, position information can be handled stably while utilizing the original functions of large language models (LLM unit 30) (natural language chat and code generation).

Furthermore, by preparing standard data 51 and error messages 61, incorporating them into system components, and operating the whole, users can create construction model data 41 that is consistent without excess or deficiency while being based on natural language dialogue. By improving this human creativity, detailed needs and requests from clients can be heard, and it is possible to provide a work environment that allows people to focus on the essential work of construction. Simultaneously, users beginning to learn design and construction, users unfamiliar with IT, and expert designers with standard data 51 in their heads can all enjoy creating through natural inspiration in natural language, improving the high-burden process of inputting construction model data 41 in the construction industry.

By utilizing the systems of each embodiment, construction model data 41 that meets client needs can be created using diverse natural language, and as construction work that can utilize construction model data 41 increases, productivity improvements envisioned by BIM and others can be realistically disseminated to construction sites.

As described above, according to Embodiment 3, since input promotion processing 28 causes the LLM unit 30 to refer to design process data 54 and generate reply messages 12 that prompt input of content to be designed following the state of construction model data 41, input in standard and desirable sequences as design processes can be encouraged, and users can be asked to make decisions so that no items are missing from construction model data 41.

Users can naturally learn what content should be input following the state of the latest construction model data 41 according to previous inputs through message-based dialogue, and can examine essentially required matters in desirable sequences without stress in the standard order of design.

This suppresses wasteful work in design phases, enables diverse people to execute natural and high-quality design in standard processes without stress, and can provide users with productive and fulfilling work experiences.

Since consistent construction model data 41 without excess or deficiency can be created by answering questions in natural language in an orderly manner without advanced learning of IT or CAD, diverse personnel can quickly create construction model data 41 as desired, and as a result, utilization of construction model data 41 can be broadly delivered to the construction industry.

### Embodiment 4

Referring again to FIG. 1 (Embodiment 1), FIG. 5 (Embodiment 2), and FIG. 10 (Embodiment 3), basic operations and extension examples regarding common processing are disclosed as Embodiment 4. The description regarding this Embodiment 4 is not suitable for direct reference when interpreting the meanings of terms in the claims, and the disclosure content of Embodiments 1 to 3 should be referenced first.

Terminal 2 is a device for users to access the systems of each embodiment, including PCs, tablets, smartphones, etc. Chat and operations are performed through user interfaces controlled for display on page 6.

Page 6 is a user interface of a front server functioning as rendering unit 10, and is an input/output device that performs construction model design through natural language dialogue. Input natural language is displayed in chat area 7, and generated three-dimensional data (3D objects) are drawn on canvas 8.

For input in chat area 7, both keyboard and voice message (language) input can be supported. Input language (text, input messages 11) and generated text (reply messages 12) received from controller 20 in response are displayed.

Controller 20 can be made independent as a controller server.

Canvas 8 draws three-dimensional data 13 (3D objects) received from controller 22. Through operations on this canvas 8, the following functions can be implemented as functions of rendering unit 10 without using natural language processing 30, but are not essential:
−Import of BIM files (IFC files, etc.)
−Display and output of generated construction model data 41 as 2D drawings such as floor plans, cross-sections, and elevations
−Display/hide of various structures (objects) constituting construction model data 41 or by certain segments
−Direct addition, updating, and deletion of structures through user data input rather than input messages 11

### Controller 20 (Controller Server, Control Unit)

Serves as the core of the systems in each embodiment, and by coordinating with rendering unit 10 (front server), LLM unit 30 (large-scale natural language processing model), construction model DB 40, and conversation log DB 70 (conversation log database 70), comprehensively realizes the functions of the entire system. It is a control device.

Controller 20 can implement the following functions:
+Message Processing
−Receive input messages 11 inputted by users from rendering unit 10
−Send input messages 11 to LLM unit 30
−Send reply messages 12 (response messages) to users from LLM unit 30 to rendering unit 10
−Database (construction model DB 40) operations
−Receive instruction codes 31 for operating databases (reading, adding, updating, deleting) from LLM unit 30
−Execute operations on databases based on instruction codes 31 from LLM unit 30
−Send database operation results to LLM unit 30
−When database operation results fail, refer to error message table 60 and send error messages 61 to LLM unit 30, requesting regeneration of instruction codes 31 for database operations or generation of execution failure reply messages 12
+Data Conversion
−Convert construction model data 41 into data formats displayable on canvas 8 of rendering unit 10
+Management and Review Processing
−Control of complex processing flows according to situations and refresh processing using construction model data 41
−As refresh processing, error processing of inappropriately placed structures
−Detect collisions (interference) between structures in response to review processing or refresh processing instructions. For example, whether large beams are placed in collision with column positions
−Detects inappropriate structures (objects) that do not conform to the standard data 51 or the design process data 54 in response to instructions for review processing or refresh processing. For example, a main beam not being connected to a column.

### LLM Unit 30 (Large-Scale Natural Language Processing Server)

The LLM unit 30 analyzes input messages 11 from users according to control by controller 20, determines appropriate actions (generation of instruction codes 31 for database operations and reply messages 12), and additionally makes proposals to users. It is a natural language processing model.

The LLM unit 30 is a separate server from controller 20 and can be accessed using APIs provided by large-scale natural language processing servers. Additionally, depending on the scale of large-scale natural language processing, it may be executed locally on the computer where controller 20 is executed.

The LLM unit 30 realizes the following functions according to control by controller 20:
Receive user input messages 11 from controller 20
−Analyze content of input messages 11 from users
−Determine necessity of operating construction model DB 40
−Generate instruction codes 31 to operate construction model DB 40
−Generate reply messages 12 to users
−Suggest necessary additional information when input messages 11 from users are insufficient (auto-complete process 23 referring to standard data 51)
−Suggest next actions to take after current work is completed (input promotion processing 28)
−Send reply messages 12 to controller 20
−Send instruction codes 31 for operating construction model DB 40 to controller 20
−Receive operation results of construction model DB 40 from controller 20
−When operation of construction model DB 40 fails, receive failure reasons (error messages 61)
−When operation of construction model DB 40 fails and is recreation type, regenerate instruction codes 31 to operate database based on error messages 61 (by recreation processing 26)
−When operation of construction model DB 40 fails and is execution failure type, generate reply messages 12 containing target non-existence based on error messages 61 (by execution failure process 27)

### Construction Model DB 40 (Data Storage Unit)

A device (database) that performs reading, addition, updating, and deletion according to instruction codes 31 received from controller 20, and stores (saves) data of structures (construction model objects).

Construction Model DB 40 has the following functions:
−Adding (saving) data
−Reading data
−Updating data
−Deleting data
−Verifying consistency against the data type

### INDUSTRIAL APPLICABILITY

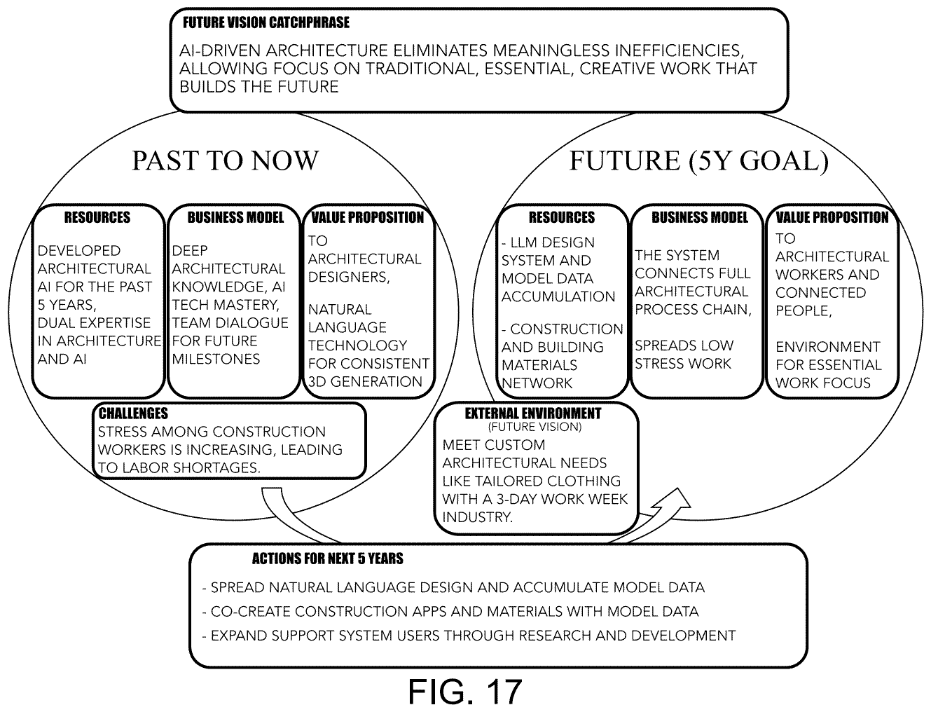

FIG. 17 shows a business design sheet indicating the industrial applicability of the invention according to the applicant's concept. The future vision is a vision that, while having technical backing, is not a technical disclosure but a managerial direction.

The business design sheet shown in FIG. 17 is a concept of the applicant individually or a company to be established.

First, by initially releasing systems and services related to this invention, technology that enables architectural designers to generate three-dimensionally consistent construction model data 41 in natural language will be delivered. This is the value provided to customers and the social environment, and for this purpose, through understanding of architecture and research into the applicability of AI technology, what can be done at present as a waypoint toward the future will be identified and implemented in systems.

The resources useful for this are the dual expertise in architecture and AI that the applicant possesses. For example, the applicant focuses on the stress of working people as a cause of labor shortages in the construction industry. The current situation in the construction industry, where people are overwhelmed by wasteful reporting, wasteful deliberation, and complicated coordination and cannot concentrate on work they should originally be doing, becomes stress for all related people.

Reporting and coordination can be solved through digitization, but input of construction model data 41 as the starting point has not penetrated, construction model data 41 that can be used throughout construction processes has not increased, and efficiency improvement of reporting and coordination work at each construction site has not progressed.

In response to this, the construction process support system, method, and program according to the present invention can provide architectural designers with a creative environment for construction model data 41 that is consistent without excess or deficiency in natural language, through cooperation between rendering unit 10 and controller 20 while using large language models as components. When construction model data 41 that specifies not only line drawings but whether it is a column and what material it is made of is prepared from the design stage and sites where it can be used increase, it becomes a foundation for efficiency improvement of entire construction processes.

In the future vision shown in FIG. 17, the applicant will provide environments where people connected starting from those working in the construction industry—for example, building material manufacturers, furniture and home appliance manufacturers, condominium management associations, and people involved in renovation work—can each concentrate on essential construction work. To provide this value, the utilization of the construction process support system, method, and program according to the present invention and this embodiment will be promoted.

The construction process support system according to the present invention and its construction model data 41 will enable chain-like connection of the entire construction process chain, automation of reporting, and automatic formulation of coordination plans. This will eliminate inefficient and stressful work for people working in the construction industry and those connected to them.

The resources necessary for this are design support in natural language according to the present invention and this embodiment, accumulation of construction model data 41, and furthermore, networks with construction and building material manufacturers. Industrial challenges cannot be solved entirely through technology alone, and relational capital such as networks between business operators in processes is also necessary, but construction model data 41 becomes attractive in building networks.

Creating that attractiveness (construction model data 41) is currently difficult, but with the construction process support system according to the present invention and this embodiment, diverse personnel can easily create construction model data 41 according to client needs and requests with minimal instructions in natural language, with accuracy that can be confirmed with three-dimensional data 13. Therefore, widespread penetration of construction model data 41 can be expected.

The construction process support system of the present invention and this embodiment can directly and indirectly contribute to responding to architectural needs like selecting custom-made clothing in a construction industry that has achieved, for example, a three-day weekend.

Note that the content shown in FIG. 17 is a vision regarding managerial industrial applicability, and even if business operators that have not achieved three-day weekends exist in the future, this does not narrow the scope of rights of the present invention.

Interpretation of terms in the claims of the present invention should refer to the descriptions of corresponding Embodiments 1 to 3 when necessary, and should not directly refer to descriptions of Embodiment 4 or industrial applicability to interpret the meaning of terms or the overall scope.

### DESCRIPTION OF REFERENCE NUMERALS

2 Terminal
4 Network
6 Page
7 Chat area
8 Canvas
10 Rendering unit
11 Input message
12 Reply message
13 Three-dimensional data
14 Chat process
15 Three-dimensional rendering process
16 Surface process
20 Controller
21 Grid label
22 Position information process
23 Completion process
24 Reply process
25 Extraction process
26 Recreation process
27 Execution failure process
28 Input promotion process
30 Large Language Model (LLM) unit (natural language processing unit)
31 Instruction code
40 Construction model database (DB)
41 Construction model data
50 Standard data table
51 Standard data
52 Customized standard data
54 Design process data
60 Error message table
61 Error message
70 Conversation log database (DB)
71 Conversation log

What is claimed is:

1. A construction process support system comprising:
one or more hardware processors;
one or more software modules; and
one or more databases;
wherein the software modules are configured to, when executed by the processors using the database, cause the system to perform the following operations:
(a) display pages serving as user interfaces to user terminals;
(b) control input messages received as natural language data from the terminals;
(c) request a Large Language Model (LLM) to generate instruction codes describing construction model data including grid labels as position information for construction structures of the construction model when input messages contain grid labels specifying coordinates on the pages with character codes;
(d) generate the requested instruction codes by the LLM from the input messages;
(e) store the construction model data as searchable data in the database from the instruction codes;
(f) forward, to chat areas of the pages, the input messages; and
(g) render, to canvases of the pages, each structure of the construction model data read from the database as three-dimensional data at positions specified by the grid labels of the structures.

2. The construction process support system of claim 1, wherein the software modules are further configured to cause the system to:
(h) provide the LLM with predetermined standard data for construction;
(i) generate responses with construction model data that includes auto-completed information insufficient in the input messages regarding structures by using both conversational context with the user and the standard data; and
(j) render surfaces of the three-dimensional data based on materials of the structures that are either specified by the user or auto-completed.

3. The construction process support system of claim 2, wherein the software modules are further configured to cause the system to:
(k) generate reply messages to the user related to content of updates in response to updates of the construction model data to the construction model database by the LLM;
(l) store time-series data of the input messages and the reply messages as conversation logs in a conversation log database provided alongside the construction model database; and
(m) extract customized standard data corresponding to each user attribute by referencing the conversation logs through the LLM to match configuration of the standard data.

4. The construction process support system of claim 1, wherein the software modules are further configured to cause the system to:
(n) provide an error message table that pre-records error messages in natural language data pointing out insufficient specification of data items or non-existence of targets by instruction codes regarding errors in execution results of the instruction codes generated by the LLM;
(o) request the LLM to reference the error messages and recreate the instruction codes upon detecting insufficient specification errors of the data items in execution results of the instruction codes; and
(p) display the error messages on the pages upon detecting non-existence errors of the targets in execution results of the instruction codes.

5. The construction process support system of claim 1, wherein the software modules are further configured to cause the system to:
(q) request the LLM to reference predetermined design process data as standard design processes and generate reply messages that prompt input of content to be designed following the state of the construction model data.

6. A method for construction process support performed by one or more hardware processors using one or more databases, the method comprising:
(a) displaying pages serving as user interfaces to user terminals;
(b) receiving input messages inputted as natural language data in chat areas of the pages via a network and displaying the input messages in the chat areas;
(c) requesting a Large Language Model (LLM) to generate instruction codes using grid labels as position information for construction structures of construction model data when input messages contain grid labels specifying coordinates in canvases of the pages with character codes;
(d) generating the instruction codes describing construction model data that specifies position information of the structures with the grid labels by LLM processing from the input messages;
(e) storing construction model data as searchable data in the database from the instruction codes; and
(f) rendering, to canvases of the pages, each structure of construction model data read from the database as three-dimensional data at positions specified by the grid labels of the structures.

7. A non-transitory computer-readable storage medium storing executable instructions that, when executed by one or more hardware processors using one or more databases, cause the processors to perform the following operations:
(a) displaying pages serving as user interfaces to user terminals;
(b) receiving input messages inputted as natural language data in chat areas of the pages via a network and displaying the input messages in the chat areas;
(c) requesting a Large Language Model (LLM) to generate instruction codes using grid labels as position information for construction structures of construction model data when input messages contain grid labels specifying coordinates in canvases of the pages with character codes;
(d) generating the instruction codes describing construction model data that specifies position information of the structures with the grid labels by LLM processing from the input messages;
(e) storing construction model data as searchable data in the database from the instruction codes; and
(f) rendering, to canvases of the pages, each structure of construction model data read from the database as three-dimensional data at positions specified by the grid labels of the structures.
